(19) United States
(12) Patent Application Publication
(10) Pub. No.: US 2026/0314338 A1
(43) Pub. Date: Oct. 8, 2026

(54) SEMICONDUCTOR DEVICES HAVING CRACK DETECTION STRUCTURE

(71) Applicant: SAMSUNG ELECTRONICS CO., LTD., Suwon-si (KR)

(72) Inventors: Yujin Kim, Suwon-si (KR); Jinwoo Han, Suwon-si (KR); Juhyun Kim, Suwon-si (KR); Hyeoncheol Kim, Suwon-si (KR)

(73) Assignee: SAMSUNG ELECTRONICS CO., LTD., Suwon-si (KR)

(21) Appl. No.: 19/562,334

(22) Filed: Mar. 10, 2026

(30) Foreign Application Priority Data
Apr. 3, 2025 (KR) 10-2025-0043306

(51) Int. Cl. H10P 74/00; H10B 12/00

(52) U.S. Cl. CPC H10P 74/273; H10B 12/30; H10B 12/50

(57) ABSTRACT

A semiconductor device includes a first structure, a second structure on the first structure in a vertical direction, and a crack detection structure. The first structure includes memory cells, cell routing interconnection structures coupled with the memory cells, and a cell insulation structure. The crack detection structure includes a plurality of crack detection lines disposed over the first structure and the second structure and at least partially surrounding the peripheral circuit area. Each of the plurality of crack detection lines includes a lower detection interconnection structure within the cell insulation structure, an upper detection interconnection structure within the peripheral insulation structure, and a detection plug at least partially penetrating through a portion of the peripheral insulation structure, the semiconductor body, the rear insulating layer, and a portion of the cell insulation structure, and coupling the lower detection interconnection structure with the upper detection interconnection structure.

### CROSS-REFERENCE TO RELATED APPLICATIONS

This application claims priority under 35 U.S.C. § 119 to Korean Patent Application No. 10-2025-0043306, filed on April 3, 2025, in the Korean Intellectual Property Office, the disclosure of which is incorporated by reference herein in its entirety.

### BACKGROUND

The present disclosure relates generally to semiconductor devices and more particularly, to a semiconductor device having a crack detection structure.

Recent improvements in packaging technologies for semiconductor devices may attempt to increase integration levels and/or performance of the semiconductor devices. Accordingly, vertically stacking semiconductor devices in which semiconductor chips on which an integrated circuit is implemented may have been developed. For example, a stacked semiconductor device may be mounted on a semiconductor package substrate while the semiconductor chips may be electrically connected to each other through a through-silicon via (TSV). However, cracks may occur at interfaces between the semiconductor chips and/or within each of the semiconductor chips due to the manufacturing process of the semiconductor device in the semiconductor chips connected through the TSV. Thus, there exists a need for further improvements in semiconductor technologies, as the need for increases in integration levels and/or performance of the semiconductor devices may be constrained by an ability to detect cracks that may occur at interfaces between the semiconductor chips and within each of the semiconductor chips through testing. Improvements are presented herein. These improvements may also be applicable to other semiconductor technologies.

### SUMMARY

One or more example embodiments of the present disclosure provide a semiconductor device having an improved reliability, when compared to related semiconductor devices.

However, the present disclosure is not limited to the above-described technical aspects, and may be variously expanded without departing from the spirit and domain of the present disclosure.

According to an aspect of the present disclosure, a semiconductor device includes a first structure, a second structure on the first structure in a vertical direction, and a crack detection structure. The first structure includes memory cells, cell routing interconnection structures coupled with the memory cells, and a cell insulation structure at least partially covering the memory cells and the cell routing interconnection structures. The second structure at least partially overlaps the first structure and includes a peripheral circuit area. The crack detection structure includes a plurality of crack detection lines disposed over the first structure and the second structure and at least partially surrounding the peripheral circuit area. The crack detection lines of the plurality of crack detection lines are coupled with each other. The second structure includes a semiconductor body including peripheral active areas, a rear insulating layer below the semiconductor body and bonded to the cell insulation structure, peripheral transistors disposed in the peripheral circuit area and within the peripheral active areas, and a peripheral insulation structure on the semiconductor body and at least partially covering the peripheral transistors. Each crack detection line of the plurality of crack detection lines includes a lower detection interconnection structure within the cell insulation structure, an upper detection interconnection structure within the peripheral insulation structure, and a detection plug at least partially penetrating through a portion of the peripheral insulation structure, the semiconductor body, the rear insulating layer, and a portion of the cell insulation structure, and coupling the lower detection interconnection structure with the upper detection interconnection structure.

According to an aspect of the present disclosure, a semiconductor device includes a first structure including a memory area, a second structure including a peripheral circuit area on the first structure in a vertical direction and at least partially overlapping the memory area, and a crack detection structure including a plurality of crack detection lines disposed over the first structure and the second structure and at least partially surrounding the peripheral circuit area, an input pad on the second structure coupled with the plurality of crack detection lines, and an output pad on the second structure coupled with the plurality of crack detection lines. The crack detection lines of the plurality of crack detection lines are coupled with each other. The second structure includes a semiconductor body including peripheral active areas, a rear insulating layer below the semiconductor body, a peripheral transistor in the peripheral circuit area and within the peripheral active areas, a peripheral insulation structure on the semiconductor body, a peripheral routing interconnection structure within the peripheral insulation structure and coupled with the peripheral transistor, and a peripheral contact plug in the peripheral circuit area, coupled with the peripheral routing interconnection structure, and at least partially penetrating through the semiconductor body and the rear insulating layer. The peripheral transistor includes a first peripheral source/drain, a second peripheral source/drain, a peripheral channel region between the first peripheral source/drain and the second peripheral source/drain, and a peripheral gate on the peripheral channel region. Each crack detection line of the plurality of crack detection lines includes a lower detection interconnection structure within the first structure, an upper detection interconnection structure within the peripheral insulation structure, and a detection plug at least partially penetrating through the peripheral insulation structure below the upper detection interconnection structure, the semiconductor body and the rear insulating layer, and coupling the lower detection interconnection structure with the upper detection interconnection structure.

According to an aspect of the present disclosure, a semiconductor device includes a first structure, a second structure on the first structure, and a crack detection structure. The first structure includes a semiconductor substrate, and a first insulation structure at least partially covering the semiconductor substrate. The crack detection structure includes a plurality of crack detection lines disposed over the first structure and the second structure, and at least one repeater between the plurality of crack detection lines. The crack detection lines of the plurality of crack detection lines are coupled with each other. The second structure includes a semiconductor body including active areas, a rear insulating layer below the semiconductor body and in contact with the first insulation structure, transistors disposed within the active areas, and a second insulation structure at least partially covering the semiconductor body and the transistors. The crack detection structure at least partially surrounds the transistors. The plurality of crack detection lines include a lower detection interconnection structure within the first insulation structure, an upper detection interconnection structure within the second insulation structure, and a detection plug at least partially penetrating through a portion of the second insulation structure below the upper detection interconnection structure, the semiconductor body, the rear insulating layer, and a portion of the first insulation structure on the lower detection interconnection structure, and coupling the lower detection interconnection structure with the upper detection interconnection structure.

Advantages and effects of the present application are not limited to the foregoing content and may be variously expanded without departing from the spirit and domain of the present disclosure.

### BRIEF DESCRIPTION OF DRAWINGS

The above and other aspects, features, and advantages of certain embodiments of the present disclosure may be more apparent from the following description, taken in conjunction with the accompanying drawings, in which:

FIG. 1 is a schematic perspective view of a semiconductor device, according to example embodiments of the present disclosure;

FIG. 2A is a schematic plan view of the semiconductor device of FIG. 1, according to example embodiments of the present disclosure;

FIG. 2B is a schematic plan view illustrating a plurality of banks and circuit areas of the semiconductor device of FIG. 1, according to example embodiments of the present disclosure;

FIG. 3 is a circuit diagram of a memory cell disposed in a memory area of a first structure, according to example embodiments of the present disclosure;

FIG. 4 is a schematic plan view of the first structure of the semiconductor device of FIG. 1, according to example embodiments of the present disclosure;

FIG. 5 is a cross-sectional view illustrating an embodiment taken along line I–I' of the semiconductor device of FIGS. 2A and 4, according to example embodiments of the present disclosure;

FIG. 6A is a circuit diagram illustrating an embodiment of the crack detection structure of FIG. 1, according to example embodiments of the present disclosure;

FIG. 6B is a circuit diagram illustrating an embodiment of a repeater included in the crack detection structure of FIG. 6A, according to example embodiments of the present disclosure;

FIG. 7 is a cross-sectional view illustrating an embodiment of the crack detection structure of the semiconductor device of FIG. 1, according to example embodiments of the present disclosure;

FIG. 8 is an enlarged view of an embodiment of region A of the crack detection structure illustrated in FIG. 7, according to example embodiments of the present disclosure;

FIG. 9 is a flowchart illustrating a crack detection method of a semiconductor device, according to example embodiments of the present disclosure;

FIG. 10 is a block diagram illustrating a crack detection system, according to an example embodiment of the present disclosure; and

FIGS. 11A, 11B, 12A, 12B, 13A and 13B are cross-sectional views illustrating an embodiment of a method of manufacturing a semiconductor device of FIG. 1, according to example embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

In the present disclosure, the articles “a” and “an” are intended to include one or more items, and may be used interchangeably with “one or more.” Where only one item is intended, the term “one” or similar language may be used.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, or the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, or the like may be used to distinguish components from each other and do not limit the present disclosure. For example, the terms “first”, “second”, “third”, or the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

As used herein, each of the terms “Al₂O₃”, “CoSi₂”, “Hf₂O₃”, “SiCN”, “Si₃N₄”, “SiO₂”, “SiOC”, “SiON”, “TaN”, “TiN”, “TiSi”, “WN”, “WSi₂”, “ZrO₂” or the like may refer to a material made of elements included in each of the terms and is not a chemical formula representing a stoichiometric relationship.

Hereinafter, various embodiments of the present disclosure are described with reference to the accompanying drawings.

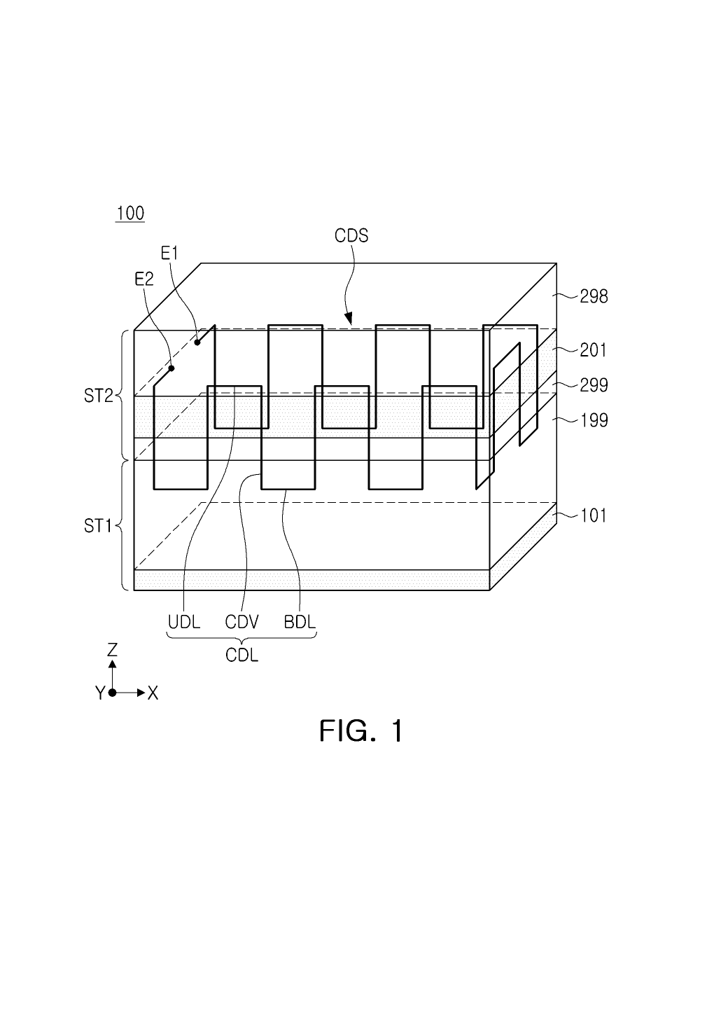

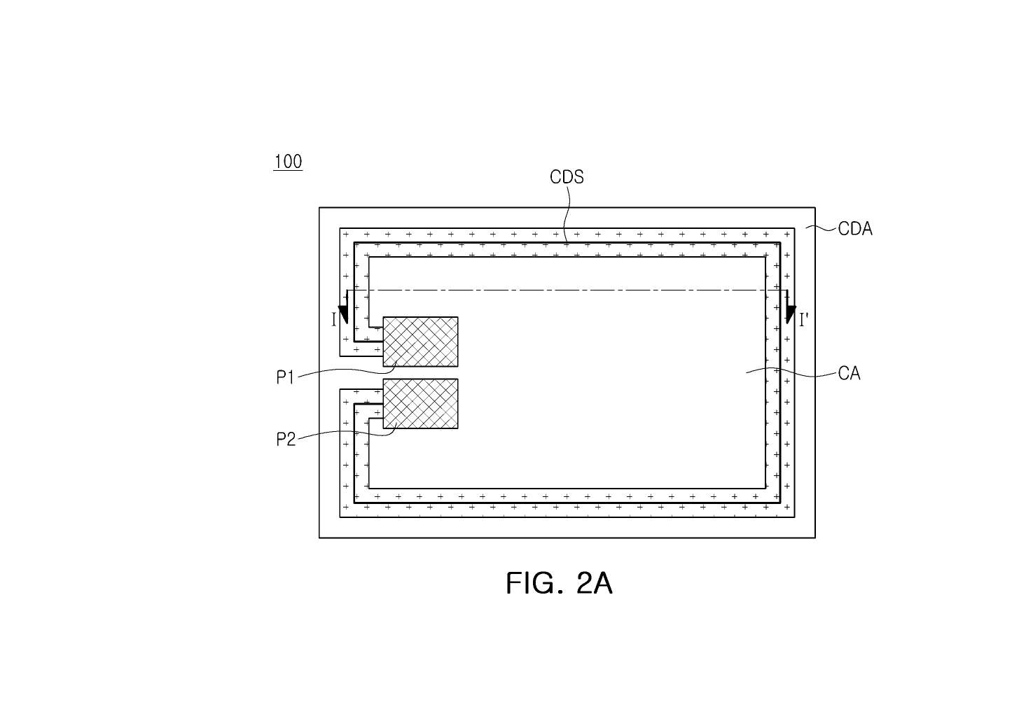

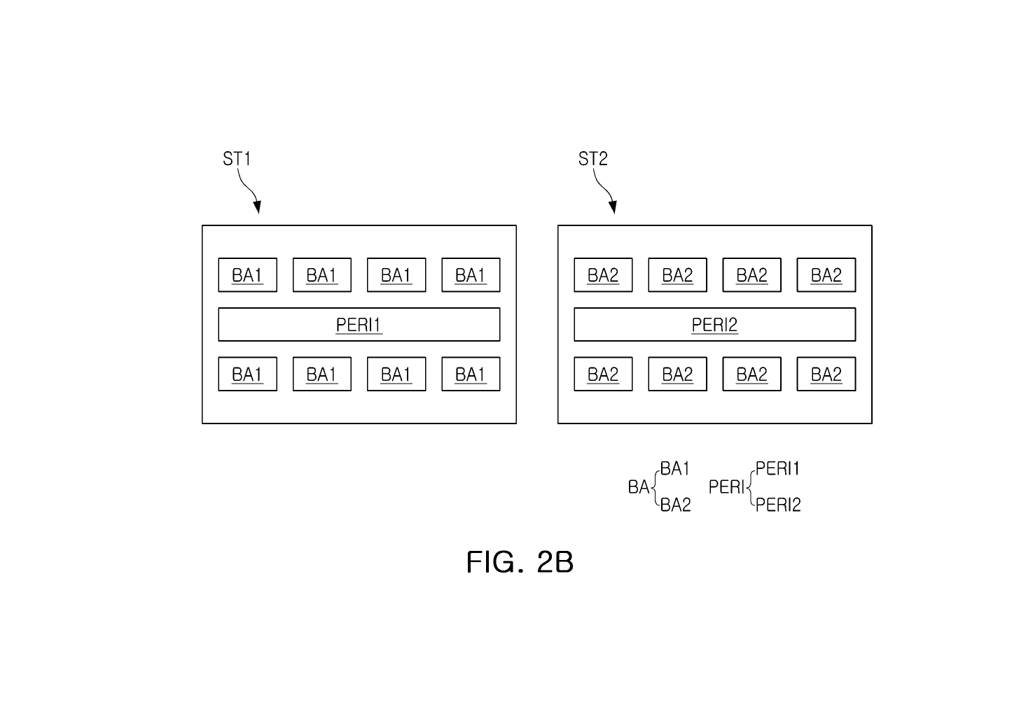

FIG. 1 is a schematic perspective view of a semiconductor device, according to example embodiments of the present disclosure. FIG. 2A is a schematic plan view of the semiconductor device of FIG. 1, according to example embodiments of the present disclosure. FIG. 2B is a schematic plan view illustrating a plurality of banks and circuit areas of the semiconductor device of FIG. 1, according to example embodiments of the present disclosure.

Referring to FIG. 1, a semiconductor device 100 may include a first structure ST1, a second structure ST2 overlapping the first structure ST1 in a vertical direction (Z-direction), and a crack detection structure CDS disposed over the first structure ST1 and the second structure ST2. The second structure ST2 may be disposed on the first structure ST1.

The first structure ST1 may be and/or may include a first chip structure including memory cells, and the second structure ST2 may be and/or may include a second chip structure including peripheral circuits that may operate the memory cells. The first structure ST1 and the second structure ST2 may be formed by being bonded in a bonding process such as, but not limited to, a wafer bonding process. Accordingly, the first structure ST1 may be in contact with and/or bonded to the second structure ST2.

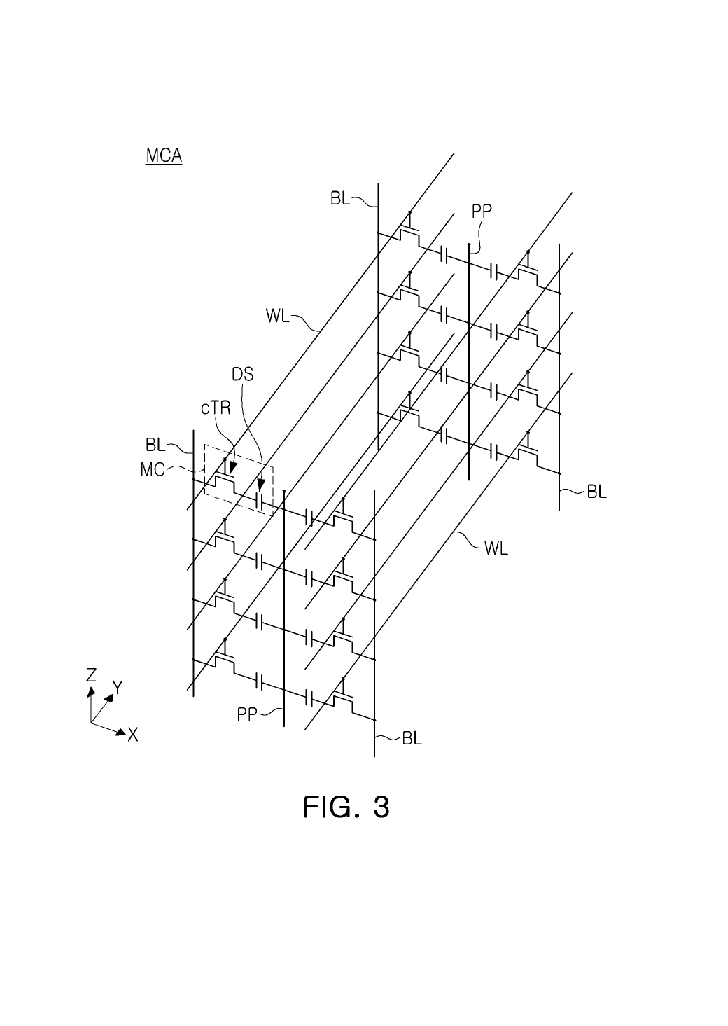

The first structure ST1 may include a semiconductor substrate 101 and a cell insulation structure 199 disposed on the semiconductor substrate 101. A plurality of memory cells may be disposed on the semiconductor substrate 101. For example, memory cells MC of FIG. 3 may be disposed on the semiconductor substrate 101. As another example, the first structure ST1 of the semiconductor device 100 may be described on the premise that the first structure ST1 includes vertically-stacked dynamic random-access memory (VS DRAM) memory cells. However, the type of the memory cell is not limited thereto and may be variously changed. For example, the memory cell may include a 2D memory such as, but not limited to, a DRAM having a buried channel array transistor (BCAT) structure, and/or a 3D memory such as, but not limited to, a ferroelectric field-effect transistor (3D FeFET) and a 3D monolithic. As another example, the first structure ST1 may be and/or may include a nonvolatile memory structure, and the first structure ST1 may be and/or may include a NAND flash memory structure.

In an example embodiment, the second structure ST2 may include a semiconductor body 201, a rear insulating layer 299 disposed below the semiconductor body 201, and a peripheral insulation structure 298 disposed on the semiconductor body 201.

The first structure ST1 and the second structure ST2 may be bonded to each other as the cell insulation structure 199 of the first structure ST1 and the rear insulating layer 299 of the second structure ST2 are bonded to each other.

As used herein, the cell insulation structure 199 may be referred to as a first insulation structure, and the peripheral insulation structure 298 may be referred to as a second insulation structure.

Referring to FIGS. 2A and 2B, the semiconductor device 100 may include a central area CA and a crack detection area CDA surrounding the central area CA. A plurality of banks BA and a circuit area PERI may be disposed in the central area CA of the semiconductor device 100. The crack detection structure CDS may be disposed in the crack detection area CDA. The crack detection area CDA of the semiconductor device 100 may have a circular loop shape surrounding the central area CA and disposed along an edge of the semiconductor device 100. However, embodiments of the present disclosure are not limited thereto. For example, the crack detection area CDA may be in the form of an open curve disposed along the edge of the semiconductor device 100.

The central area CA of the semiconductor device 100 may include the plurality of banks BA and the circuit areas PERI.

Each of the plurality of banks BA may include a first bank area BA1 in the first structure ST1 and a second bank area BA2 in the second structure ST2. The circuit areas PERI may include a first circuit area PERI1 in the first structure ST1 and a second circuit area PERI2 in the second structure ST2. The circuit area PERI may be and/or may include a circuit area in which peripheral circuits for input/output of data and/or commands, and/or input of power/ground are disposed.

The first bank area BA1 in the first structure ST1 may include a memory area MCA of FIG. 3.

The second bank area BA2 in the second structure ST2 may include core circuit areas. The core circuit areas may be arranged in a first direction (X-direction) and a second direction (Y-direction). The core circuit areas may include, but not be limited to, sense amplifiers and sub word line drivers.

The first circuit area PERI1 of the first structure ST1 and the second circuit area PERI2 of the second structure ST2 may include a control circuit that may control the sense amplifier and the sub word line driver.

As used herein, the second bank area BA2 of the second structure ST2 and the second circuit area PERI2 may be referred to as a peripheral circuit area. The central area CA of the second structure ST2 may also be referred to as a peripheral circuit area.

The crack detection structure CDS may be and/or may include a structure for inspecting whether a crack occurs in the first structure ST1 and the second structure ST2 of the semiconductor device 100.

In an example embodiment, the crack detection structure CDS may be disposed within the crack detection area CDA, and may be disposed within the first structure ST1 and the second structure ST2. The crack detection structure CDS may include a plurality of crack detection lines CDL connected to each other. The crack detection structure CDS may have a circular loop shape disposed along edges of the first structure ST1 and the second structure ST2. The crack detection structure CDS may further include an input terminal E1 disposed in one end of the circular loop, an output terminal E2 disposed in the other end of the circular loop, an input pad P1 connected to the input terminal E1, and an output pad P2 connected to the output terminal E2.

Each of the crack detection lines CDL may include a lower detection interconnection structure BDL, an upper detection interconnection structure UDL, and a detection plug CDV connecting the lower detection interconnection structure BDL and the upper detection interconnection structure UDL. For example, the lower detection interconnection structure BDL may be disposed within the cell insulation structure 199 of the first structure ST1, and the upper detection interconnection structure UDL may be disposed within the peripheral insulation structure 298 of the second structure ST2. The detection plug CDV may penetrate through a portion of the peripheral insulation structure 298, the semiconductor body 201, the rear insulating layer 299, and a portion of the cell insulation structure 199, and may connect the lower detection interconnection structure BDL and the upper detection interconnection structure UDL.

In an example embodiment, adjacent crack detection lines CDL may be connected to each other through the upper detection interconnection structure UDL or the lower detection interconnection structure BDL. For example, two adjacent crack detection lines CDL may be connected to each other by sharing the lower detection interconnection structures BDL or the upper detection interconnection structures UDL. As another example, the crack detection lines CDL may include first to n-th crack detection lines disposed sequentially in a horizontal direction, and the detection plugs CDV of the crack detection lines CDL may include first to n-th detection plugs disposed sequentially in the horizontal direction, where n is a positive integer greater than one (1). As another example, the first crack detection line and the second crack detection line may be connected to each other by sharing the lower detection interconnection structure BDL, and the second crack detection line and the third crack detection line may be connected to each other by sharing the upper detection interconnection structure UDL. The third crack detection line and the fourth crack detection line may be connected to each other by sharing the lower detection interconnection structure BDL. The (n-1)-th crack detection line and the n-th crack detection line may be connected to each other by sharing the lower detection interconnection structure BDL.

A test input signal may be applied through the input pad P1 connected to the input terminal E1 of the crack detection structure CDS and the test input signal may be transmitted to the plurality of crack detection lines CDL, and a test output signal corresponding to the test input signal may be received through the output pad P2 connected to the output terminal E2 of the crack detection structure CDS. Based on the test input signal and the test output signal, it may be determined whether a crack occurs in the semiconductor device 100. That is, at least one crack occurring inside each of the cell insulation structure 199 of the first structure ST1, the rear insulating layer 299 of the second structure ST2, the semiconductor body 201 and the peripheral insulation structure 298 may be detected through the crack detection structure CDS. In addition, a crack occurring between the rear insulating layer 299 and the cell insulation structure 199, which is a bonded interface between the first structure ST1 and the second structure ST2, a crack occurring between the rear insulating layer 299 and the semiconductor body 201, and/or a crack occurring between the semiconductor body 201 and the peripheral insulation structure 298 may be detected through the crack detection structure CDS.

FIG. 3 is a circuit diagram of a memory cell disposed in a memory area of a first structure, according to example embodiments of the present disclosure.

Referring to FIG. 3, the memory area MCA may be included in the first bank area BA1 of the first structure ST1 of FIG. 2A. The memory area MCA may include memory cells MC arranged in the first direction (X-direction) and the second direction (Y-direction), word lines WL connected to the memory cells MC and extending in the second direction (Y-direction), and bit lines BL connected to the memory cells MC and extending in the vertical direction (Z-direction). Each of the memory cells MC may include a cell transistor cTR and information storage structures DS that may serve as information storage.

The memory cells MC may have a structure in which two or more memory cells are stacked in the vertical direction (Z-direction). For example, two memory cells MC may be arranged as a pair in the horizontal direction. A gate of the cell transistor cTR may be connected to the word line WL, a first source/drain region of the cell transistor cTR may be connected to the bit line BL, and a second source/drain region of the cell transistor cTR may be connected to the information storage structure DS.

The cell transistor cTR and the information storage structure DS may be disposed in a horizontal arrangement extending in the first direction (X-direction). Adjacent information storage structures DS may share a plate electrode PP. The plate electrode PP may extend in the vertical direction (Z-direction) and may be electrically connected to the information storage structures DS. The plate electrode PP may be vertically oriented. The plate electrode PP may be referred to as a vertical plate electrode. Two memory cells MC arranged in the horizontal direction as a pair may share one plate electrode PP. Each of the information storage structures DS and the plate electrode PP may function as a cell capacitor of each of the memory cells MC. The information storage structure DS and the plate electrode PP may be referred to as an information storage structure.

The memory cells MC may be disposed between the bit lines BL and the plate electrode PP. The memory cells MC may be disposed in a horizontal arrangement in the first direction (X-direction). Each of the memory cells MC may be connected to one bit line of the bit lines BL, one word line of the word lines WL, and one plate electrode of the plate electrodes PP.

The word lines WL may be spaced apart from each other in the first direction (X-direction) and may extend in the second direction (Y-direction). The word lines WL may be arranged in the vertical direction (Z-direction). For example, the word lines WL may be horizontally oriented with respect to a plane of the first structure ST1. The word lines WL may be referred to as horizontal word lines. A plurality of memory cells MC arranged horizontally in the second direction (Y-direction) may be connected to one word line WL.

The bit lines BL may be spaced apart from each other in the second direction (Y-direction) and may extend in the third direction (Z-direction). The bit lines BL may be vertically oriented from the plane of the second structure ST2. The bit lines BL may be referred to as vertical bit lines.

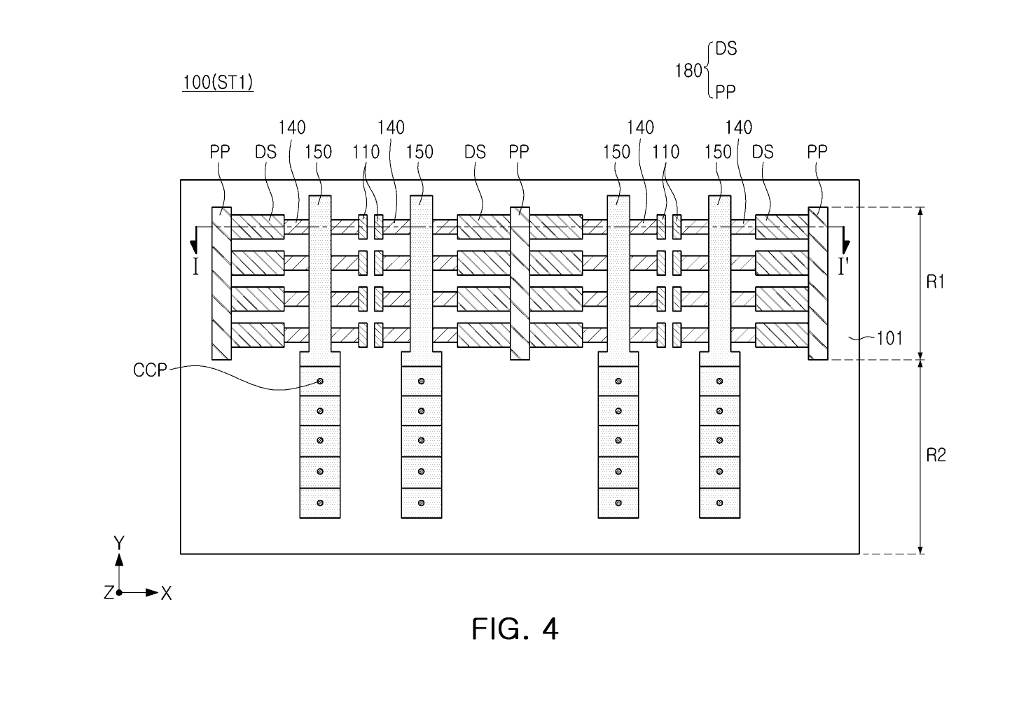

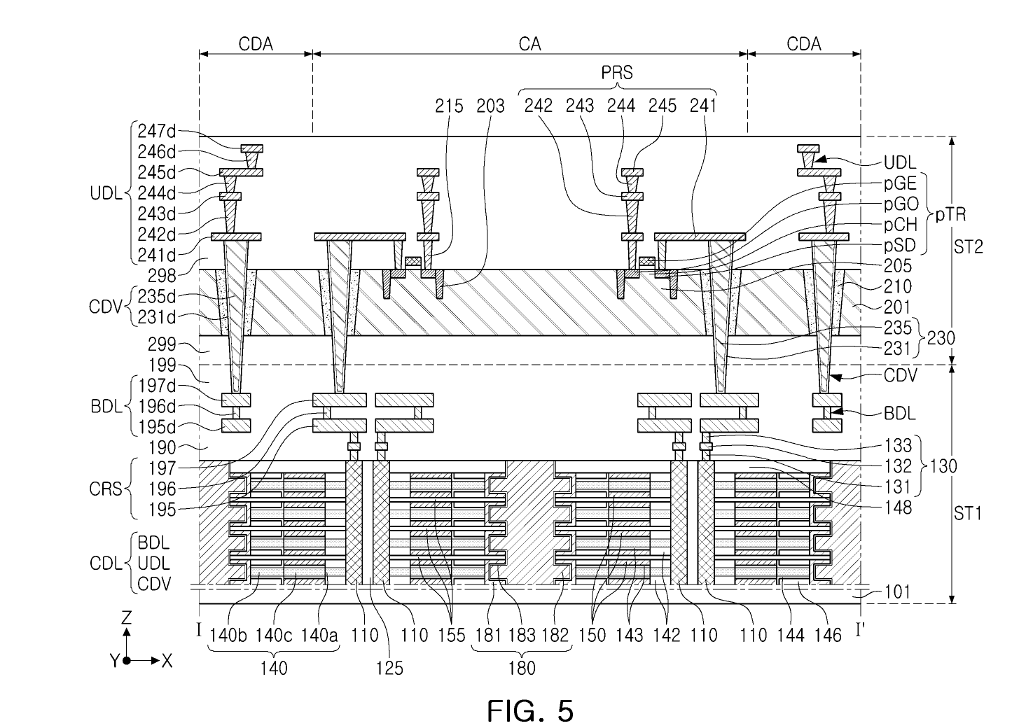

FIG. 4 is a schematic plan view of a first structure of the semiconductor device of FIG. 1, according to example embodiments of the present disclosure. FIG. 5 is a cross-sectional view illustrating an example embodiment of the semiconductor device of FIGS. 2A and 4 along line I–I', according to example embodiments of the present disclosure.

Referring to FIGS. 4 and 5, the first structure ST1 may include a semiconductor substrate 101 including a first region R1 and a second region R2. The first region R1 of the semiconductor substrate 101 may include bit lines 110, channel structures 140, gate electrodes 150, and information storage structures 180. The gate electrodes 150 extending from the first region R1 and gate contact plugs CCP connected to the gate electrodes 150 may be disposed in the second region R2 of the semiconductor substrate 101. The first region R1 and the second region R2 may be disposed side by side in the second direction (Y-direction).

The semiconductor substrate 101 may include a semiconductor material, such as, but not limited to, a group IV semiconductor, a group III-V compound semiconductor, or a group II-VI compound semiconductor. A substrate 103 may be provided as a bulk wafer or an epitaxial layer. For example, the semiconductor substrate 101 may be bulk silicon or a silicon-on-insulator (SOI).

The first structure ST1 of the semiconductor device 100 may include, for example, a cell array of a DRAM. The bit lines 110 may correspond to the bit lines BL of FIG. 3, the gate electrodes 150 may correspond to the word lines WL of FIG. 3, and the information storage structure 180 may correspond to the information storage structure DS and the plate electrode PP of FIG. 3. Consequently, repeated descriptions of the bit lines 110, the gate electrodes 150, and the information storage structure 180 described above with reference to FIG. 3 may be omitted for the sake of brevity.

The bit lines 110 may extend vertically in the third direction (Z-direction) on the semiconductor substrate 101. The bit lines 110 may be spaced apart from each other in the first direction (X-direction) and the second direction (Y-direction). One bit line 110 may be electrically connected to a plurality of channel structures 140 stacked in the third direction (Z-direction). For example, the bit line 110 may be electrically connected to first impurity regions 140a. The bit lines 110 may have at least one of a line shape, a bar shape, or a pillar shape extending in the third direction (Z-direction). The bit lines 110 may include at least one of a doped semiconductor material, a conductive metal nitride, a metal, or a metal-semiconductor compound.

The channel structures 140 may extend horizontally on a semiconductor substrate 101 in the first direction (X-direction). The channel structures 140 may be spaced apart from each other in the second direction (Y-direction) and the third direction (Y-direction). In the plan view, the channel structures 140 may have at least one of a line shape, a bar shape, or a pillar shape extending in the first direction (X-direction), intersecting the gate electrodes 150. For example, the channel structures 140 may include a semiconductor material, for example, silicon (Si), germanium (Ge), or silicon-germanium (Si-Ge).

Each of the channel structures 140 may include a first impurity region 140a, a second impurity region 140b, and a channel region 140c. The channel region 140c may be disposed between the first impurity region 140a and the second impurity region 140b. The first impurity region 140a may be in contact with the bit line 110 and may be electrically connected to the bit line 110. The second impurity region 140b may be in contact with a first electrode 181 of the information storage structure 180 and may be electrically connected to the first electrode 181. A length of the first impurity region 140a in the first direction (X-direction) and a length of the second impurity region 140b in the first direction (X-direction) may be different from or substantially similar or equal to each other. The channel region 140c may overlap the gate electrodes 150 in the third direction (Z-direction). When the channel structure 140 is formed of a semiconductor material, each of the first impurity region 140a and the second impurity region 140b may include impurities, and the impurities may have an N-type or P-type conductivity.

At least a portion of the first impurity region 140a may correspond to the first source/drain region of the cell transistor cTR of FIG. 3, and at least a portion of the second impurity region 140b may correspond to the second source/drain region of the cell transistor cTR of FIG. 3, and the channel region 140c may correspond to the channel region of the cell transistor cTR of FIG. 3. The first impurity region 140a may provide a region for directly connecting the cell transistor cTR of FIG. 3 to the bit line BL, and the second impurity region 140b may provide a region for directly connecting the cell transistor cTR of FIG. 3 to the information storage structure DS.

The gate electrodes 150 may be disposed on the semiconductor substrate 101 and may extend horizontally in the second direction (Y-direction). The gate electrodes 150 may be spaced apart from each other in the first direction (X-direction) and the third direction (Z-direction). The gate electrodes 150 may be disposed between channel regions 140c of the channel structure 140. In the plan view, the gate electrodes 150 may have a line shape, a bar shape, or a pillar shape.

The gate electrodes 150 may include a conductive material, and the conductive material may include at least one of a doped semiconductor material (e.g., doped silicon, doped germanium, or the like), a conductive metal nitride (e.g., titanium nitride (TiN), tantalum nitride (TaN), tungsten nitride (WN), or the like), a metal (e.g., tungsten (W), titanium (Ti), tantalum (Ta), cobalt (Co), aluminum (Al), ruthenium (Ru), or the like), and a metal-semiconductor compound (e.g., tungsten silicide (WSi₂), cobalt silicide (CoSi₂), titanium silicide (TiSi), or the like).

The gate electrode 150 may be disposed in a gate all around structure surrounding the channel structure 140. In an example embodiment, the gate electrodes 150 may be disposed in a double gate structure. For example, the gate electrodes 150 may be disposed on an upper surface and a lower surface of each channel structure 140, and two gate electrodes 150 adjacent to each channel structure 140 may form one word line WL. In an example embodiment, the gate electrodes 150 may be disposed in a single gate structure. For example, one of the gate electrodes 150 may be disposed adjacently to each channel structure 140, and one gate electrode 150 may form one word line WL.

The first structure ST1 of the semiconductor device 100 may further include a spacer 142, a gate dielectric layer 143, a first capping pattern 144, and a second capping pattern 146.

The spacer 142 may be disposed between the gate electrode 150 and the bit line 110. The spacer 142 may overlap the first impurity region 140a of the channel structure 140 in the third direction (Z-direction). The spacer 142 may include at least one of silicon nitride (Si₃N₄), silicon oxynitride (SiON), or silicon oxycarbide (SiOC). For example, the spacer 142 may include silicon nitride (Si₃N₄).

The gate dielectric layer 143 may be disposed to surround the channel structure 140 between the channel structure 140 and the gate electrode 150. The gate dielectric layers 143 may cover an upper surface and a lower surface of each channel structure 140. The gate dielectric layer 143 may include at least one of silicon oxide (SiO₂), silicon nitride (Si₃N₄), a low-ĸ material, and a high-ĸ material.

The first capping pattern 144 and the second capping pattern 146 may be disposed between the gate electrode 150 and the information storage structure 180. The first capping pattern 144 and the second capping pattern 146 may overlap the second impurity region 140b of the channel structure 140 in the third direction (Z-direction). The first capping pattern 144 may be in contact with the second impurity region 140b, the gate electrode 150 and the gate dielectric layer 143. The second capping pattern 146 may be arranged on the first capping pattern 144. The first capping pattern 144 and the second capping pattern 146 may include at least one of silicon nitride (Si₃N₄), silicon oxynitride (SiON), and silicon oxycarbide (SiOC).

The first structure ST1 of the semiconductor device 100 may further include an interlayer insulating layer 155. The interlayer insulating layer 155 may be disposed between channel structures 140 adjacent in the third direction (Z-direction) and between gate electrodes 150 adjacent in the third direction (Z-direction). The interlayer insulating layer 155 may extend in the horizontal direction, and may be spaced apart from each other in the third direction (Z-direction). One end of the interlayer insulating layer 155 may be in contact with a side surface of the bit line 110, and the other end of the interlayer insulating layer 155 may be disposed between the first electrodes 181 of the information storage structure 180. An upper surface and a lower surface of the interlayer insulating layer 155 may be in contact with the gate electrode 150, the spacer 142, the first capping pattern 144 and the second capping pattern 146. The interlayer insulating layer 155 may electrically insulate the adjacent gate electrodes 150 from each other. For example, the interlayer insulating layer 155 may include at least one of silicon oxide (SiO₂), silicon nitride (Si₃N₄), silicon oxynitride (SiON), or silicon oxycarbide (SiOC). For example, the interlayer insulating layer 155 may include silicon oxide (SiO₂).

The first structure ST1 of the semiconductor device 100 may further include a vertical insulating pillar 125. The vertical insulating pillar 125 may be disposed between bit lines 110 adjacent in the first direction (X-direction). The vertical insulating pillars 125 may extend in the third direction (Z-direction) and may be spaced apart in the first direction (X-direction). The vertical insulating pillars 125 may insulate the adjacent bit lines 110 from each other. For example, the vertical insulating pillars 125 may include at least one of silicon oxide (SiO₂), silicon nitride (Si₃N₄), silicon oxynitride (SiON), or silicon oxycarbide (SiOC). For example, the vertical insulating pillar 125 may include silicon oxide (SiO₂).

The information storage structure 180 may include a first electrode 181, a second electrode 182, and a capacitor dielectric 183 between the first and second electrodes 181 and 182. The information storage structure 180 may provide a plurality of information storage structures DS and plate electrodes PP connected to the plurality of information storage structures DS. For example, portions of the first electrode 181 and the second electrode 182 overlapping the first electrode 181 in the third direction (Z-direction) and the capacitor dielectric 183 may be referred to as the information storage structure DS. The plate electrode PP may extend in the third direction (Z-direction) and may be electrically connected to the information storage structures DS. For example, the plate electrode PP may be comprised of the second electrode 182.

The information storage structure 180 may be in contact with the second impurity region 140b of the channel structure 140. The information storage structure 180 may be electrically connected to the second impurity region 140b of the channel structure 140. The first electrode 181 may have a cylinder shape. However, embodiments of the present disclosure are not limited thereto, and the first electrode 181 may have a pillar shape, according to an example embodiment.

The first electrodes 181 may be in a node-separated state, and for example, the first electrodes 181 may be electrically insulated from each other by an interlayer insulating layer 155. As used herein, the first electrodes 181 may be referred to as storage node electrodes. The first electrodes 181 may include at least one of a doped semiconductor material, a conductive metal nitride, a metal, or a metal-semiconductor compound.

The capacitor dielectric 183 may conformally cover the first electrode 181. The capacitor dielectric 183 may include, for example, at least one of a high-ĸ material such as, but not limited to, zirconium oxide (ZrO₂), aluminum oxide (Al₂O₃), or hafnium oxide (Hf₂O₃).

The second electrode 182 may cover the capacitor dielectric 183 and may extend in the first direction (X-direction). At least a portion of the second electrode 182 may be referred to as a plate electrode PP. The second electrode 182 may include at least one of a doped semiconductor material, a conductive metal nitride, a metal, or a metal-semiconductor compound.

The first structure ST1 of the semiconductor device 100 may further include a capping layer 148. The capping layer 148 may be disposed on an uppermost gate electrode 150, among the gate electrodes 150, and may be in contact with side surfaces of the bit line 110 and the information storage structure 180. Each of the capping layers 148 may extend in the first direction (X-direction) and may be spaced apart from each other in the first direction (X-direction). An upper surface of the capping layers 148 may be coplanar with an upper surface of the bit lines 110. For example, the capping layer 148 may include at least one of silicon oxide (SiO₂), silicon nitride (Si₃N₄), silicon oxynitride (SiON), or silicon oxycarbide (SiOC). For example, the capping layer 148 may include silicon oxide (SiO₂).

A first structure ST1 of a semiconductor device 100, according to example embodiments of the present disclosure, may further include a cell insulation structure 199, cell routing interconnection structures CRS disposed within the cell insulation structure 199, and lower detection interconnection structures BDL of the crack detection structure CDS. The semiconductor device 100 may further include a bit line contact structure 130 disposed within the cell insulation structure 199 and connected to the bit lines 110.

The cell insulation structure 199 may be disposed on the capping layer 148, bit lines 110, and information storage structure 180. The cell insulation structure 199 may include a plurality of insulating layers. The cell insulation structure 199 may include an insulating material. For example, the cell insulation structure 199 may include silicon carbonitride (SiCN). However, embodiments of the present disclosure are not limited thereto, and for example, the cell insulation structure 199 may include at least one of silicon oxide (SiO₂), silicon nitride (Si₃N₄), silicon carbonitride (SiCN), or silicon oxynitride (SiON).

The bit line contact structure 130 and the cell routing interconnection structure CRS may be disposed in the central area CA, and the lower detection interconnection structure BDL of the crack detection structure CDS may be disposed in the crack detection area CDA.

The bit line contact structure 130 may be disposed on the bit line 110 and connected to the bit line 110. For example, the bit line contact structure 130 may include a first bit line contact via 131 in contact with the bit line 110 on the bit line 110, a bit line contact interconnection line 132 on the first bit line contact via 131, and a second bit line contact via 133 on the bit line contact interconnection line 132. The first bit line contact via 131 and the second bit line contact via 133 may have a cylindrical shape, and the bit line contact interconnection line 132 may have a line shape.

The cell routing interconnection structure CRS may be disposed within the cell insulation structure 199 and may be connected to the bit line contact structure 130. The above cell routing interconnection structure CRS may include a first cell contact interconnection line 195 disposed on a bit line contact structure 130, a cell contact via 196 on the first cell contact interconnection line 195, and a second cell contact interconnection line 197 on the cell contact via 196. The first and second contact interconnection lines 195 and 197 may have a line shape, and the cell contact via 196 may have a cylindrical shape.

The lower detection interconnection structures BDL of the crack detection structure CDS may be disposed in the crack detection area CDA within the cell insulation structure 199, and may be disposed on an outer side of the cell routing interconnection structure CRS and the bit line contact structure 130.

The lower detection interconnection structure BDL may include a first lower detection interconnection line 195d, a second lower detection interconnection line 197d on the first lower detection interconnection line 195d, and a lower detection via 196d connecting the first lower detection interconnection line 195d and the second lower detection interconnection line 197d. The lower detection interconnection structure BDL may not be connected to the cell routing interconnection structure CRS and the bit line contact structure 130. For example, the lower detection interconnection structure BDL may be disposed on the same level as the cell routing interconnection structure CRS. As another example, the first lower detection interconnection line 195d may be disposed on the same level as the first cell contact interconnection line 195, the second lower detection interconnection line 197d may be disposed on same level as the second cell contact interconnection line 197, and the lower detection via 196d may be disposed on the same level as the cell contact via 196.

The second structure ST2 may be disposed on the cell insulation structure 199. The second structure ST2 may include a semiconductor body 201 including a peripheral active area, a rear insulating layer 299 disposed below the semiconductor body 201, and a peripheral insulation structure 298 disposed on the semiconductor body 201. For example, the second structure ST2 may further include a through-insulating pattern 210 penetrating through the semiconductor body 201.

The central area CA of the second structure ST2 may further include device isolation patterns 203 defining the peripheral active area, peripheral transistors pTR, peripheral routing interconnection structures PRS connected to the peripheral contact transistors pTR, and peripheral contact plugs 230 connecting the peripheral routing interconnection structure PRS and the cell routing interconnection structure CRS, and the second structure ST2 may further include an upper detection interconnection structure UDL disposed within a peripheral insulation structure 298, and a detection plug CDV connecting the lower detection interconnection structure BDL and the upper detection interconnection structure UDL in the crack detection area CDA.

The semiconductor body 201 may include a semiconductor material, such as, but not limited to, a group IV semiconductor, a group III-V compound semiconductor, or a group II-VI compound semiconductor. For example, the group IV semiconductor may include silicon (Si), germanium (Ge), or silicon-germanium (Si-Ge). The semiconductor body 201 may include single crystal silicon.

The rear insulating layer 299 may be disposed below the semiconductor body 201. The rear insulating layer 299 may be bonded to the cell insulation structure 199 of the first structure ST1.

The device isolation patterns 203 may define peripheral active areas. The device isolation patterns 203 may be disposed between peripheral transistors pTR, and the device isolation patterns 203 may be spaced apart from each other in the horizontal direction. Each of the device isolation patterns 203 may have a width that may narrow toward a lower portion thereof. The device isolation patterns 203 may have a form embedded in an interior of the semiconductor body 201 from an upper surface of the semiconductor body 201. The device isolation patterns 203 may include, but not be limited to, silicon oxide (SiO₂) and/or silicon nitride (Si₃N₄).

The peripheral transistors pTR may be disposed on the semiconductor body 201. Each of the peripheral transistors pTR may include peripheral gate structures pGO and pGE disposed on the semiconductor body 201, first and second peripheral source/drain regions pSD disposed within the peripheral active area located on both sides of the peripheral gate structures pGO and pGE, and a peripheral channel region pCH between the first and second peripheral source/drain regions pSD. The peripheral gate structures pGO and pGE may include a peripheral gate dielectric layer pGO and a peripheral gate electrode pGE that are sequentially stacked.

The central area CA of the second structure ST2 may further include a transistor contact plug 215 connected to the peripheral transistor pTR. The transistor contact plug 215 may be connected to the first and second peripheral source/drain regions pSD.

The through-insulating pattern 210 may penetrate through the semiconductor body 201. The through-insulating pattern 210 may be spaced apart from the device isolation patterns 203 in the horizontal direction. The through-insulating pattern 210 may include an insulating material. For example, the through-insulating pattern 210 may include silicon oxide (SiO₂) and/or silicon nitride (Si₃N₄). However, embodiments of the present disclosure are not limited thereto. In an example embodiment, the through-insulating pattern 210 may include an insulating material having a low dielectric constant.

The peripheral insulation structure 298 may be disposed on the semiconductor body 201 and may cover the peripheral transistors pTR, the transistor contact plug 215, the peripheral routing interconnection structure PRS, and the upper detection interconnection structure UDL of the crack detection structure CDS.

The peripheral contact plug 230 may overlap the central area CA in the vertical direction (Z-direction), and may penetrate through the peripheral insulation structure 298 disposed below the peripheral routing interconnection structure PRS, the through-insulating pattern 210 (or the semiconductor body 201) disposed in the central area CA, the rear insulating layer 299, and the cell insulation structure 199 disposed on the cell routing interconnection structure CRS. The peripheral contact plug 230 may connect the peripheral routing interconnection structure PRS of the second structure ST2 and the cell routing interconnection structure CRS of the first structure ST1. A side surface of the peripheral contact plug 230 exposed on the semiconductor body 201 may be in contact with the peripheral insulation structure 298, and a side surface of the peripheral contact plug 230 exposed below the semiconductor body 201 may be in contact with the rear insulating layer 299 and the cell insulation structure 199. For example, the peripheral contact plug 230 may include a peripheral conductive pillar 235 and a peripheral conductive barrier layer 231 surrounding a side surface and a lower surface of the peripheral conductive pillar 235. The peripheral conductive pillar 235 may include a metal material such as, but not limited to, tungsten (W), aluminum (Al), or copper (Cu). The peripheral conductive barrier layer 231 may include a metal nitride such as, but not limited to, titanium nitride (TiN), tantalum nitride (TaN), or tungsten nitride (WN).

The peripheral routing interconnection structure PRS may be disposed within the peripheral insulation structure 298 and may overlap the central area CA in the vertical direction (Z-direction). The peripheral routing interconnection structure PRS may be connected to the transistor contact plug 215 and the peripheral contact plug 230. The peripheral routing interconnection structure PRS may be connected to the peripheral transistor pTR through the transistor contact plug 215. The peripheral transistor pTR may include a plurality of peripheral contact interconnection lines (e.g., a first peripheral contact interconnection line 241, a third peripheral contact interconnection line 243, and a first peripheral contact interconnection line 245) and a plurality of peripheral contact vias (e.g., a first peripheral contact via 242 and a second peripheral contact via 244) connecting the plurality of peripheral contact interconnection lines 241 to 245. For example, the plurality of peripheral contact interconnection lines 241 to 245 may include the first peripheral contact interconnection line 241 disposed on the transistor contact plug 215, the second peripheral contact interconnection line 243 on the first peripheral contact interconnection line 241, and the third peripheral contact interconnection line 245 on the second peripheral contact interconnection line 243. The plurality of peripheral contact vias 242 and 244 may include the first peripheral contact via 242 between the first peripheral contact interconnection line 241 and the second peripheral contact interconnection line 243, and the second peripheral contact via 244 between the second peripheral contact interconnection line 243 and the third peripheral contact interconnection line 245. Although the peripheral routing interconnection structure PRS is illustrated as including three (3) peripheral contact interconnection lines and two (2) peripheral contact vias, embodiments of the present disclosure are not limited thereto, and the number of peripheral contact interconnection lines and peripheral contact vias may be varied, according to example embodiments.

The detection plug CDV and the upper interconnection structure UDL may overlap the crack detection area CDA in the vertical direction (Z-direction). The detection plug CDV may be disposed outside the peripheral contact plugs 230, and may penetrate through the peripheral insulation structure 298 disposed below the upper detection interconnection structure UDL, the through-insulating pattern 210 (or the semiconductor body 201), the rear insulating layer 299, and the cell insulation structure 199 disposed on the lower detection interconnection structure BDL. The detection plug CDV may connect the lower detection interconnection structure BDL and the upper detection interconnection structure UDL. The detection plug CDV may be disposed on the detection plug CDV and may be connected to the detection plug CDV, and may include a detection conductive pillar 235d and a detection conductive barrier layer 231d surrounding a side surface and a lower surface of the detection conductive pillar 235d. The detection conductive pillar 235d may include a metal material such as, but not limited to, tungsten (W), aluminum (Al), or copper (Cu). The detection barrier layer 231d may include a metal nitride such as, but not limited to, titanium nitride (TiN), tantalum nitride (TaN), or tungsten nitride (WN).

The upper detection interconnection structure UDL of the crack detection structure CDS may be disposed within the peripheral insulation structure 298 and may overlap the crack detection area CDA in the vertical direction (Z-direction). The upper detection interconnection structure UDL may be disposed on the detection plug CDV and may be disposed outside the peripheral routing interconnection structure PRS and peripheral transistors pTR. For example, the upper detection interconnection structure UDL may include a plurality of upper detection interconnection lines (e.g., a first upper detection interconnection line 241d, a second upper detection interconnection line 243d, a third upper detection interconnection line 245d, and a fourth upper detection interconnection line 247d) and upper detection vias (e.g., a first upper detection via 242d, a second upper detection via 244d, and a third upper detection via 246d) connecting the plurality of upper detection interconnection lines 241d to 247d. For example, the plurality of upper detection interconnection lines 241d to 247d may have a line shape, and the upper detection vias 242d to 246d may have a cylindrical shape. For example, the plurality of upper detection interconnection lines 241d to 247d may include the first upper detection interconnection line 241d, the second upper detection interconnection line 243d, the third upper detection interconnection line 245d, and the fourth upper detection interconnection line 247d, which may be sequentially disposed in the vertical direction (Z-direction). The upper detection vias 242d to 246d may include the first upper detection via 242d connecting the first and second upper detection interconnection lines 241d and 243d, the second upper detection via 244d connecting the second and third upper detection interconnection lines 243d and 245d, and the third upper detection via 246d connecting the third and fourth upper detection interconnection lines 245d and 247d.

The lower detection interconnection structure BDL in the first structure ST1 overlapping the crack detection area CDA, the upper detection interconnection structure UDL in the second structure ST2, and the detection plug CDV connecting the lower detection interconnection structure UDL and the upper detection interconnection structure UDL may form one crack detection line CDL, and the plurality of crack detection lines CDL may be connected to each other to form the crack detection structure CDS of FIG. 1. The crack detection lines CDL of the crack detection structure CDS of FIG. 1 may not overlap the peripheral routing interconnection structures PRS in the vertical direction (Z-direction). Two adjacent crack detection lines CDL may be connected to each other through the upper detection interconnection structure UDL or the lower detection interconnection structure BDL. For example, the two adjacent detection plugs CDV may be connected to each other by sharing the lower detection interconnection structure BDL or the upper detection interconnection structure UDL. The crack detection lines CDL may not be connected to cell routing interconnection structures CRL disposed in the central area CA and a peripheral routing interconnection structure PRL. The crack detection structure CDS of FIG. 1, which may be comprised of the crack detection lines CDL, may be in a floating state.

A semiconductor device, according to example embodiments of the present disclosure, may include a first structure ST1 and a second structure ST2 connected to the first structure ST1, and a crack detection structure CDS disposed over the first structure ST1 and the second structure ST2 and having an annular loop shape along the edges of the first and second structures ST1 and ST2. Accordingly, in a crack detection test process during a manufacturing process of the semiconductor device 100, a crack that may occur within a range from a lowermost end of the lower detection interconnection structure BDL disposed within the first structure ST1 through the detection plug CDV to an uppermost end of the upper detection interconnection structure UDL of the crack detection structure CDS disposed within the second structure ST2 may be detected through the crack detection structure CDS within the semiconductor device 100.

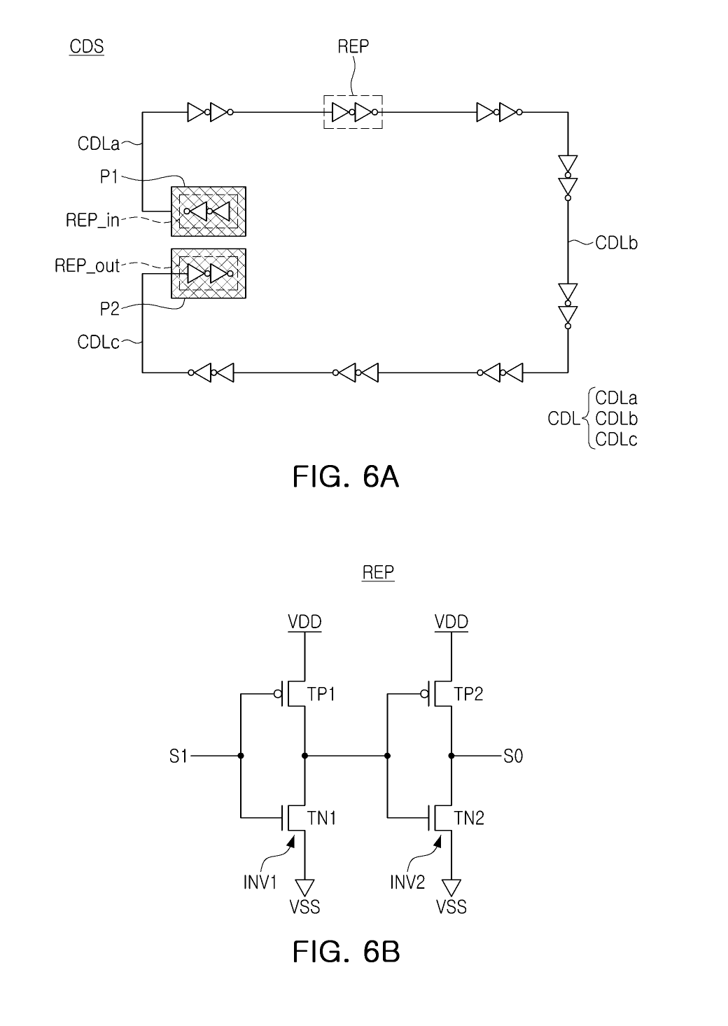

FIG. 6A is a circuit diagram, according to an example embodiment, of the crack detection structure of FIG. 1, according to example embodiments of the present disclosure. FIG. 6B is a circuit diagram illustrating an example embodiment of a repeater included in the crack detection structure of FIG. 6A, according to example embodiments of the present disclosure.

Referring to FIGS. 6A and 6B, a crack detection structure CDS may have a circular loop shape and may include crack detection lines CDL, at least one repeater REP disposed between the crack detection lines CDL, and an input pad P1 that may be connected to one end of the circular loop shape and to which a test input signal may be applied, and an output pad P2 connected to the other end of the circular loop shape and configured to receive a test output signal. For example, the crack detection structure CDS may further include an input driver REP_in connected to the input pad P1 and an output driver REP_out connected to the output pad P2.

The crack detection lines CDL may include a first crack detection line CDLa connected to the input driver REP_in, a third crack detection line CDLc connected to the output driver REP_out, and second crack detection lines CDLb disposed between the first crack detection line CDLa and the third crack detection line CDLc.

The input driver REP_in may be and/or may include a repeater disposed adjacent to one end of the crack detection structure CDS (e.g., the input terminal E1 of FIG. 1) and may amplify a test signal applied through the input pad P1. The output driver REP_out may be and/or may include a repeater disposed adjacent to the other end of the crack detection structure CDS (e.g., the output terminal E2 of FIG. 1) and may amplify a signal transmitted from the third crack detection line CDLc.

At least one repeater REP may be disposed between the first crack detection line CDLa and the second crack detection line CDLb, between the second crack detection lines CDLb, and/or between the second crack detection line CDLb and the third crack detection line CDLc. The at least one repeater REP may amplify a signal applied through the crack detection lines CDL.

FIG. 6B illustrates a repeater in which two single-stack inverters INV1 and INV2 are connected in series between an input node in which an input signal S1 is received and an output node in which an output signal S0 is output. In an example embodiment, the repeater may include three (3) or more single-stack inverters connected in series between the input node and the output node. The single stack may denote that the number of P-type transistors TP1 and TP2 and N-type transistors TN1 and TN2 connected between a first voltage VDD and a second voltage VSS is one, respectively. When an odd number of inverters are connected in series between the input node and the output node, the repeater may invert and amplify the input signal S1 to generate an output signal S0. As another example, when an even number of inverters are connected in series between the input node and the output node, the repeater may amplify the input signal S1 without inverting and may generate the output signal S0. The even number of inverters connected in series may be referred to as a buffer.

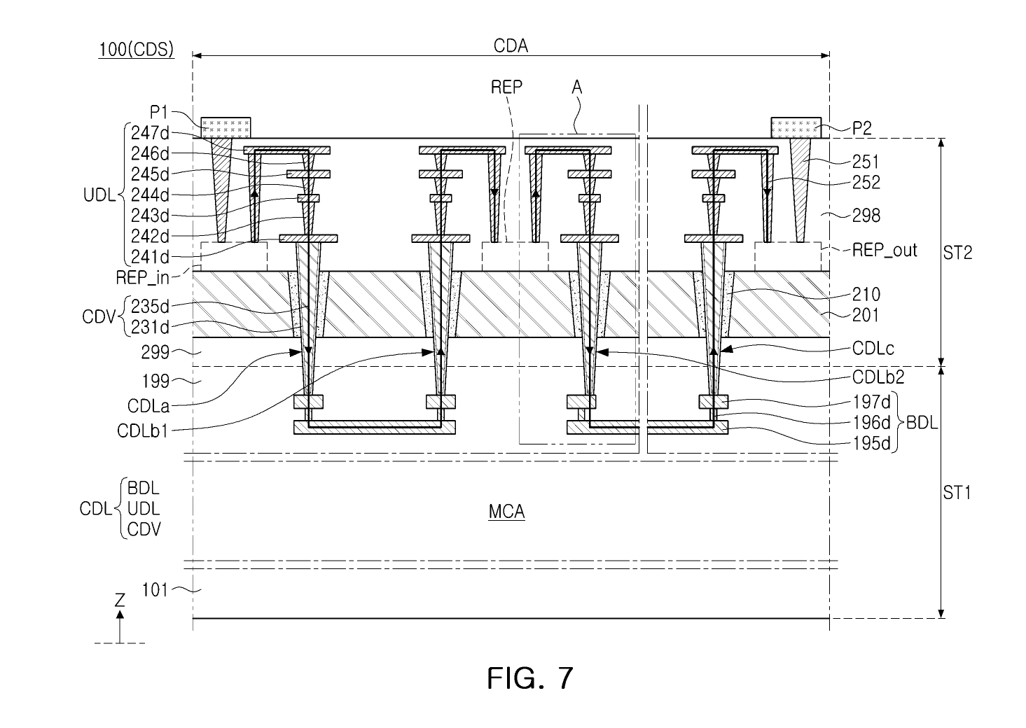

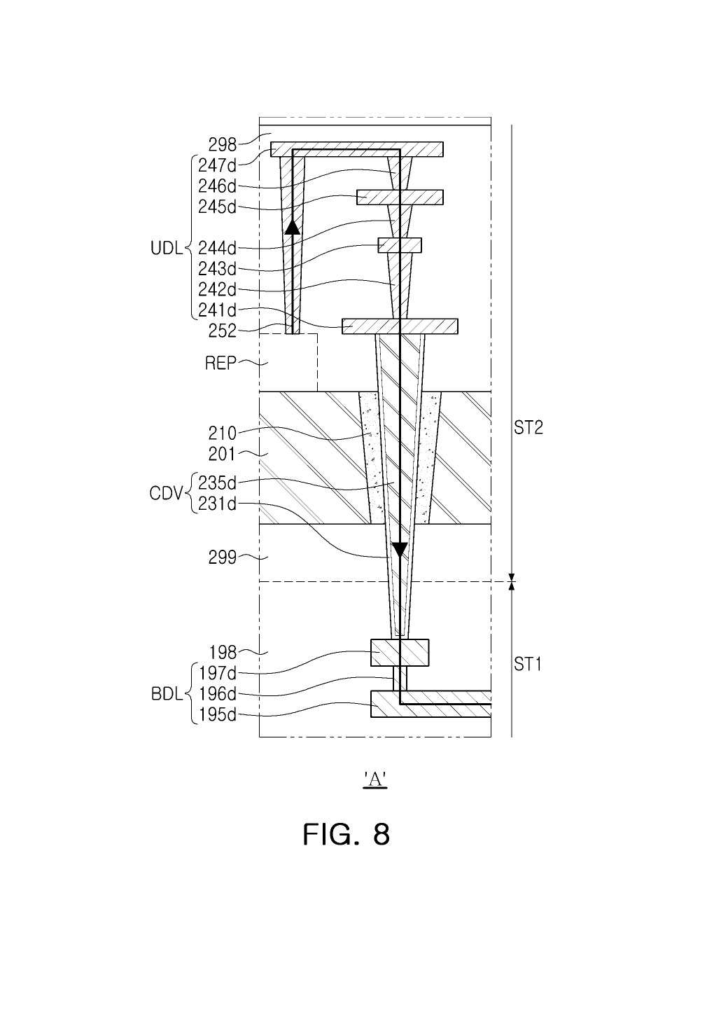

FIG. 7 is a cross-sectional view illustrating an embodiment of a crack detection structure of a semiconductor device of FIG. 1, according to example embodiments of the present disclosure. FIG. 8 is an enlarged view of an example embodiment of area 'A' of the crack detection structure illustrated in FIG. 7, according to example embodiments of the present disclosure. FIG. 7 illustrates an example embodiment of the crack detection structure CDS of FIG. 1 disposed in the crack detection area CDA.

Referring to FIGS. 7 and 8, the crack detection structure CDS may include an input pad P1, an input driver REP_in connected to the input pad P1, an output pad P2, an output driver REP_out connected to the output pad P2, a plurality of crack detection lines CDL disposed between the input driver REP_in and the output driver REP_out, and at least one repeater REP disposed between the plurality of crack detection lines CDL. For example, the crack detection structure CDS may be disposed along an edge of a memory area MCA of the first structure ST1.

The input pad P1 and the output pad P2 may be disposed on the second structure ST2. A test input signal for detecting a crack in a semiconductor device 100 may be applied through the input pad P1. A test output signal corresponding to the test input signal may be received through the output pad P2.

Respective first connection plugs 251 may be connected to the input pad P1 and the output pad P2 within the peripheral insulation structure 298. One of the first connection plugs 251 may be disposed between the input pad P1 and the input driver REP_in to connect the input pad P1 and the input driver REP_in. The first connection plug 251 connected to the input pad P1 may correspond to the input terminal E1 of FIG. 1. Another connection plug of the first connection plugs 251 may be disposed between the output pad P2 and the output driver REP_out within the peripheral insulation structure 298 to connect the output pad P2 and the output driver REP_out. The first connection plug 251 connected to the output pad P2 may correspond to the output terminal E2 of FIG. 1.

The crack detection lines CDL may include a first crack detection line CDLa adjacent to the input driver REP_in, a third crack detection line CDLb adjacent to the output driver REP_out, and second crack detection lines CDLb1 and CDLb2 disposed between the first and third crack detection lines CDLa and CLDb. The second crack detection lines CDLb1 and CDLb2 may include a second-first crack detection line CDLb1 and a second-second crack detection line CDLb2. The second-first crack detection line CDLb1 may be disposed adjacently to the first crack detection line CDLa. The second-second crack detection line CDLb2 may be disposed adjacently to the second-first crack detection line CDLb1. For example, the first crack detection line CDLa and the second-first crack detection line CDLb1 may be connected to each other by sharing a first lower detection interconnection line 195d of the lower detection interconnection structure BDL.

At least one repeater REP may be disposed between the second-first crack detection line CDLb1 and the second-second crack detection line CDLb2. The second-first crack detection line CDLb1 and the second-second crack detection line CDLb2 may be connected through upper detection interconnection structures UDL connected to the repeater REP disposed between the second-first crack detection line CDLb1 and the second-second crack detection line CDLb2. The repeater REP may be disposed in the semiconductor body 201. The repeater REP may be disposed outside the peripheral transistor pTR of FIG. 5. The repeater REP may be connected to the second-first crack detection line CDLb1 and the second-second crack detection line CDLb2 through second connection plugs 252. A signal passing through the second-first crack detection line CDLb1 may be amplified through the repeater REP and may be transmitted to the second-second crack detection line CDLb2.

The second connection plugs 252 may be connected to the input driver REP_in, the output driver REP_out and at least one repeater REP within the peripheral insulation structure 298. One of the second connection plugs 252 may be disposed between the first crack detection line CDLa and the input driver REP_in to connect the first crack detection line CDLa and the input driver REP_in. Another connection plug of the second connection plugs 252 may be disposed between the third crack detection line CDLc and the output driver REP_out within the peripheral insulation structure 298 to connect the third crack detection line CDLc and the output driver REP_out.

A test input signal applied through an input pad P1 may be amplified through the input driver REP_in and may be sequentially transmitted to the first crack detection line CDLa, the second crack detection lines CDLb1 and CDLb2, and the third crack detection line CDLc. A signal transmitted from the third crack detection line CDLc and received by an input node may be amplified through an output driver REP_out.

The first crack detection line CDLa, the second crack detection lines CDLb1 and CDLb2, and the third crack detection line CDLc may form a signal path for a test input signal applied through the input pad P1. The test input signal amplified through the input driver REP_in may be sequentially transmitted to the upper detection interconnection structure UDL, the detection plug CDV and the lower detection interconnection structure BDL of the first crack detection line CDL, and may be transmitted to the detection plug CDV and the upper detection interconnection structure UDL of the second-first crack detection line CDLb1. In such a manner, the test signal may pass through an uppermost portion of the upper detection interconnection structure UDL of each of the crack detection lines CDL, the detection plug CDV, and a lowermost portion of the lower detection interconnection structure BDL. The first lower detection interconnection line 195d of the lower detection interconnection structure BDL of the crack detection line CDL may be disposed adjacently to a lowermost end of the cell insulation structure 199, and the fourth upper detection interconnection line 247d of the upper detection interconnection structure UDL may be disposed adjacently to an uppermost end of the peripheral insulation structure 198. Therefore, in the crack detection test process of the semiconductor device 100, a crack occurring in at least one of the cell insulation structure 199 of the first structure ST1 and the rear insulating layer 299 of the second structure ST2, the semiconductor body 201, or the peripheral insulation structure 298 may be detected through one crack detection structure CDS disposed over the first and second structures ST1 and ST2.

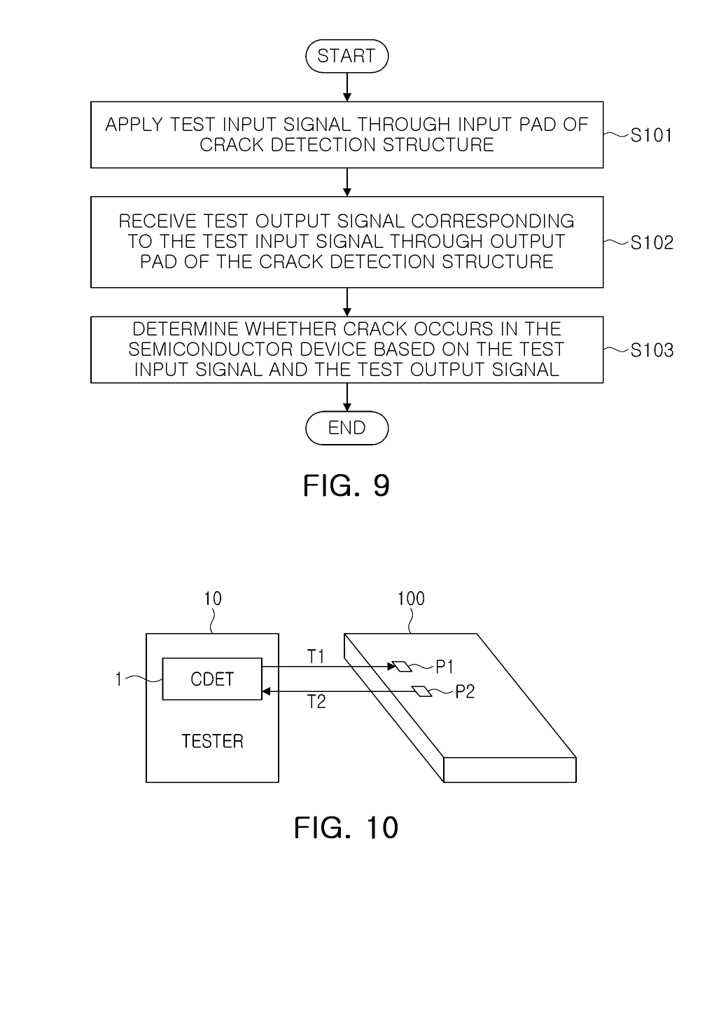

FIG. 9 is a flow chart illustrating a crack detection method of a semiconductor device, according to example embodiments of the present disclosure. FIG. 10 is a block diagram illustrating a crack detection system, according to an example embodiment of the present disclosure.

Referring to FIGS. 1, 9, and 10, the crack detection method of a semiconductor device may include an operation S101 of applying a test input signal T1 through an input pad P1 of a crack detection structure CDS, an operation S102 of receiving a test output signal T2 corresponding to the test input signal T1 through an output pad P2 of the crack detection structure CDS, and an operation S103 of determining whether a crack occurs in the semiconductor device 100 based on the test input signal T1 and the test output signal T2.

Referring to FIG. 9 together with FIG. 1, the crack detection system may include a test device 10 and a semiconductor device 100. The semiconductor device 100 may include a crack detection structure CDS of FIG. 1, and the test device 10 may be connected to the crack detection structure CDS having the annular loop shape through the input pad P1 and the output pad P2 disposed on an upper surface of the semiconductor device 100. The test device 10 may include a crack detector (CDET) 1. The crack detector 1 may apply the test input signal T1 through the input pad P1, and may receive the test output signal T2 as the test input signal T1 passes through the crack detection structure CDS. The crack detector 1 may determine whether a crack occurs in the semiconductor device 100 by comparing the test input signal T1 and the test output signal T2.

A test input signal T0 may be transmitted to the crack detection lines CDL of the crack detection structure CDS and may pass through the lower detection interconnection structure BDL, the detection plug CDV and the upper detection interconnection structure UDL of each of the crack detection lines CDL, and when a crack occurs in the first structure ST1 and/or the second structure ST2, since the characteristics of the test input signal T0, such as, but not limited to, an amplitude, a phase, and/or a period, may change, the crack detector 1 may determine whether the crack occurs in the semiconductor device 100 by comparing the test input signal T1 and the test output signal T2.

The crack detector 1 may determine that the crack occurs in the semiconductor device 100 in the case in which the crack occurs within the cell insulation structure 199 of the first structure ST1 in contact with the crack detection structure CDS and the rear insulating layer 299 of the second structure ST2, the semiconductor body 201 and the peripheral insulation structure 298, and in the case in which the crack occurs at an interface between the cell insulation structure 199 and the rear insulating layer 299, an interface between the rear insulating layer 299 and the semiconductor body 201, and an interface between the semiconductor body 201 and the peripheral insulation structure 298.

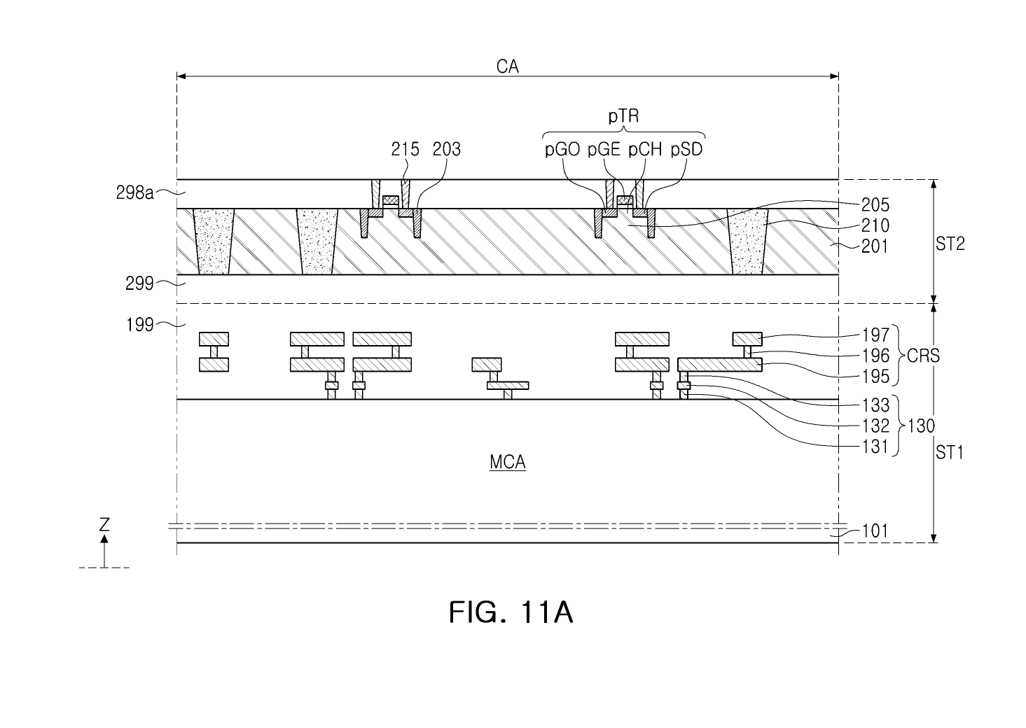

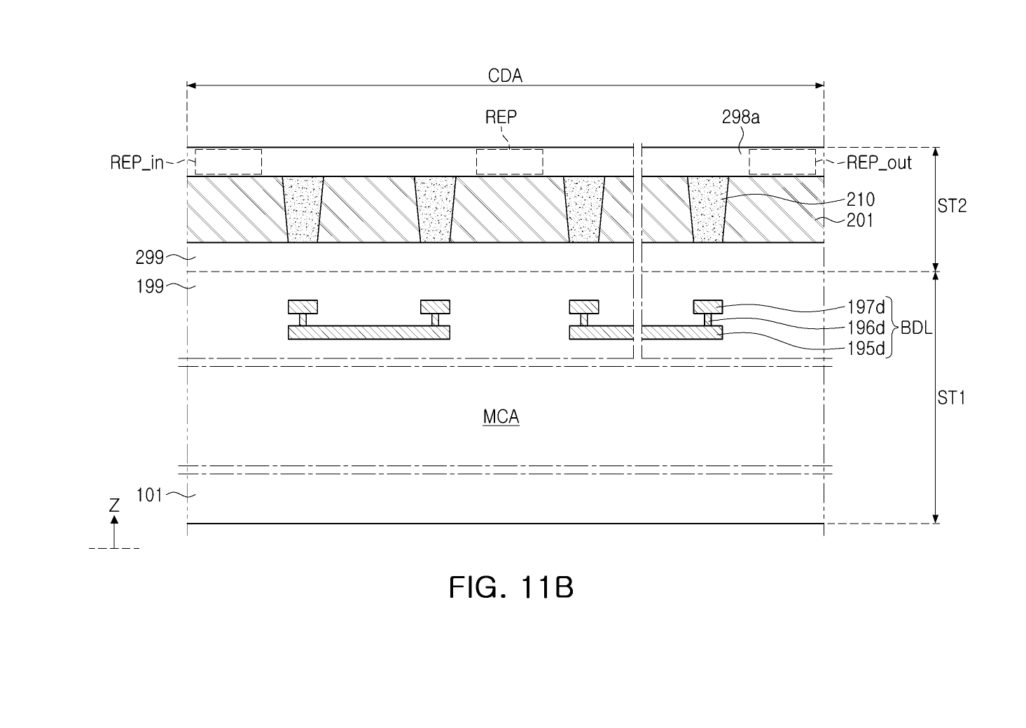

FIGS. 11A, 11B, 12A, 12B, 13A and 13B are cross-sectional views illustrating an example embodiment of a method of manufacturing a semiconductor device of FIG. 1.

Referring to FIGS. 11A, 11B, 12A, 12B, 13A and 13B, a method of manufacturing a semiconductor device may include an operation of forming a first structure ST1 including memory cells (e.g., the memory cell MC of FIG. 3), a cell routing interconnection structure CRS connected to the memory cells and formed in the central area CA, and a cell insulation structure 199 covering the memory cells and the cell routing interconnection structures CRS, an operation of forming lower detection interconnection structures BDL formed in a crack detection area CDA surrounding the central area CA within the cell insulation structure 199, an operation of forming a second structure ST2 including a semiconductor body 201, a rear insulating layer 299 formed below the semiconductor body 201, peripheral transistors pTR formed on a peripheral circuit area of the semiconductor body 201, and a first peripheral insulating layer 298a covering the semiconductor body 201 and the peripheral transistors pTR, an operation of bonding the cell insulation structure 199 of the first structure ST1 and the rear insulating layer 299 of the second structure ST2, an operation of forming peripheral contact plugs 230 overlapping the central area CA and connected to the cell routing interconnection structure CRS and detection plugs CDV overlapping the crack detection area CDA and connected to the lower detection interconnection structures BDL, and an operation of forming peripheral routing interconnection structures PRS connected to the peripheral contact plugs 230 and upper detection interconnection structures UDL connected to the detection plugs CDV.

Referring to FIGS. 11A and 11B, the forming the first structure ST1 may include preparing a semiconductor substrate 101 including a central area CA and a crack detection area CDA surrounding the central area CA along an edge of the central area CA, and forming a memory area MCA (and the memory cell MC of FIG. 3) on the semiconductor substrate 101, forming bit line contact structures 130 connected to the memory area MCA and cell routing interconnection structures CRS connected to the bit line contact structures 130, and forming a cell insulation structure 199 covering the bit line contact structures 130 and the cell routing interconnection structures CRS.

In the forming of the first structure ST1, the lower detection interconnection structures BDL may be formed in the crack detection area CDA. For example, the lower detection interconnection structure BDL may be formed in the same process as a process of forming the cell routing interconnection structure CRS. The lower detection interconnection structures BDL may be formed outside of the cell routing interconnection structures CRS. The lower detection interconnection structures BDL may not be physically and/or electrically connected to the cell routing interconnection structures CRS.

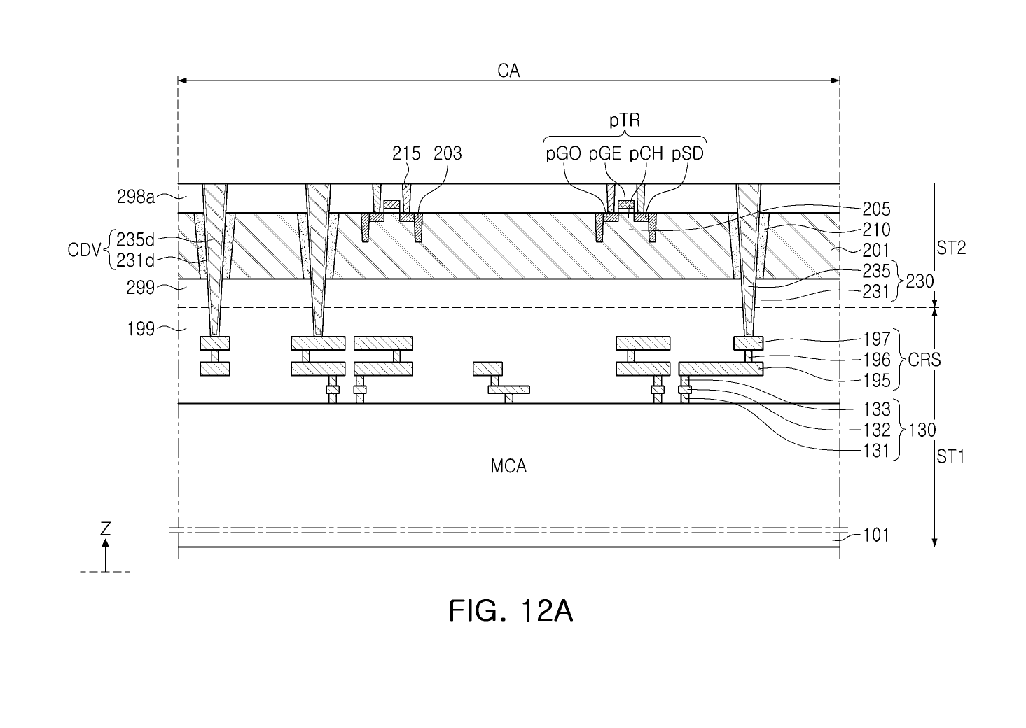

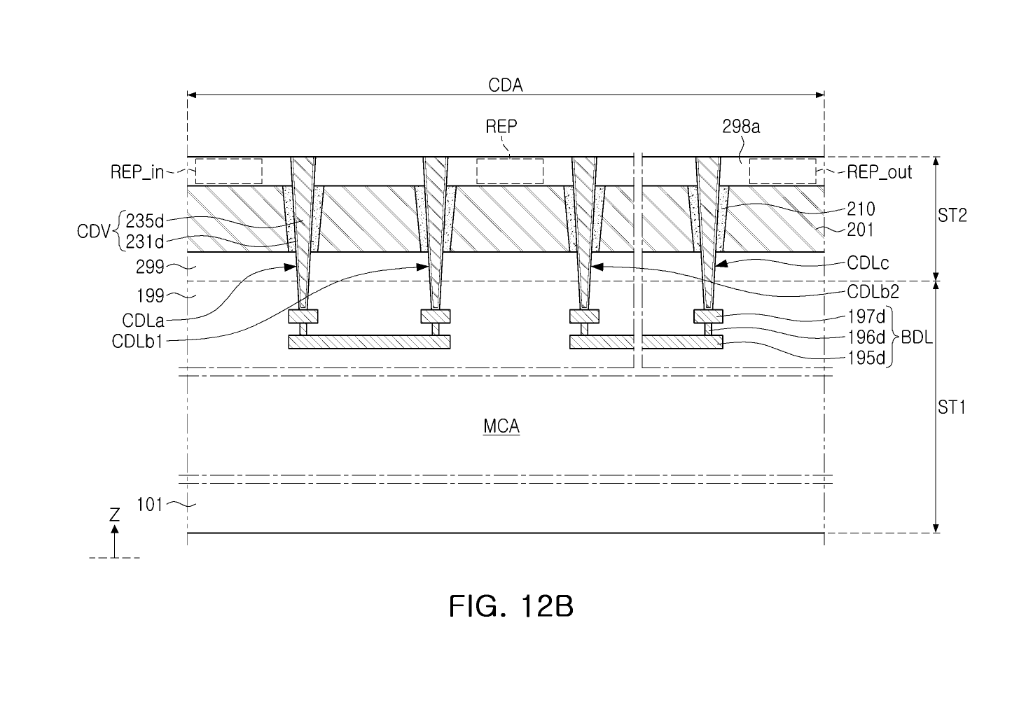

The forming the second structure ST2 may include preparing a semiconductor body 201 and forming peripheral transistors pTR in a peripheral circuit area of the semiconductor body 201, forming a through-insulating pattern 210 spaced from the peripheral transistor pTR in the horizontal direction and penetrating through the semiconductor body 201, forming a first peripheral insulating layer 298a covering the semiconductor body 201 and the peripheral transistors pTR, forming transistor contact plugs 215 penetrating through the first peripheral insulating layer 298a and connected to the peripheral transistors pTR, and forming a rear insulating layer 299 below the semiconductor body 201. The forming the second structure ST2 may further include forming an input driver REP_in, an output driver REP_out, and at least one repeater REP within a semiconductor body 201 overlapping an area surrounding the peripheral circuit area. For example, the peripheral circuit area of the semiconductor body 201 may overlap the central area CA. The through-insulating pattern 210 penetrating through the semiconductor body 201 may be a structure through which peripheral contact plugs 230 of FIG. 12A and detection plugs CDV of FIG. 12B may penetrate. In an example embodiment, the through-insulating pattern 210 may be omitted.

The cell insulation structure 199 may be bonded to the rear insulating layer 299, so that the first structure ST1 and the second structure ST2 may be bonded in a dielectric-to-dielectric bonding structure.

Referring to FIGS. 12A and 12B, the peripheral contact plugs 230 may be formed to vertically overlap the central area CA and to be connected to the cell routing interconnection structures CRS formed in the first structure ST1. The detection plugs CDV may be formed to vertically overlap the crack detection area CDA and to be connected to the lower detection interconnection structures BDL formed in the first structure ST1. Each of the peripheral contact plugs 230 and the detection plugs CDV may penetrate through a portion of the first peripheral insulating layer 298a, the through-insulating pattern 210 (or the semiconductor body 201), the rear insulating layer 299 and the cell insulation structure 199 of the first structure ST1. Each of the peripheral contact plugs 230 and the detection plugs CDV may have a cylindrical shape whose width becomes narrower toward a lower portion thereof. The peripheral contact plugs 230 may be spaced apart from the detection plugs CDV in the horizontal direction, and the detection plugs CDV may surround the peripheral contact plugs 230.

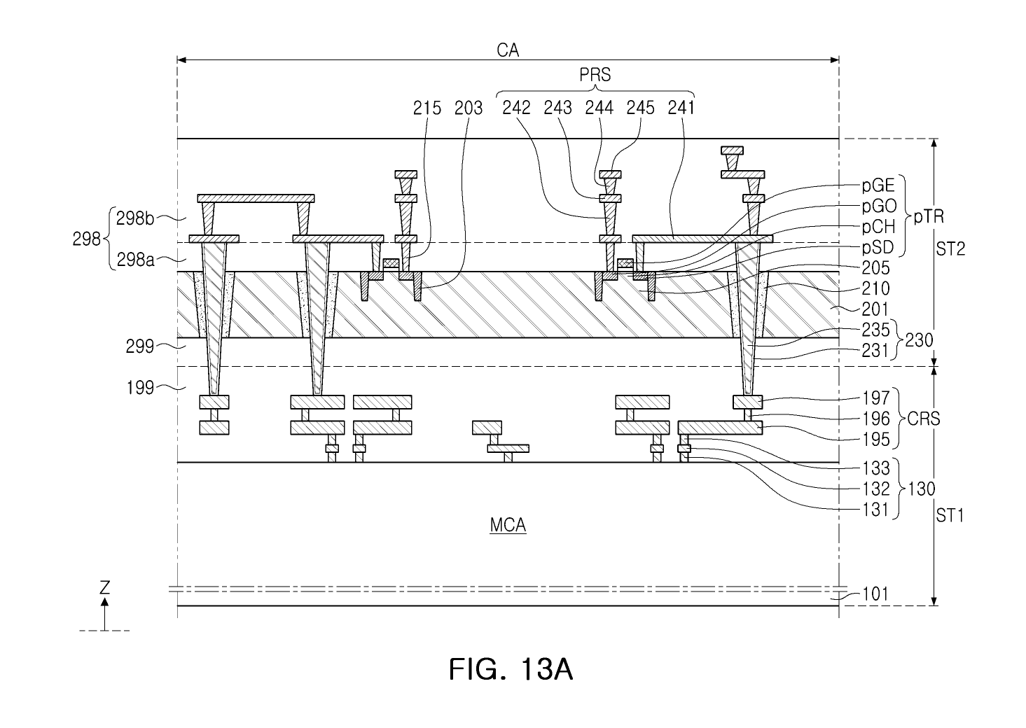

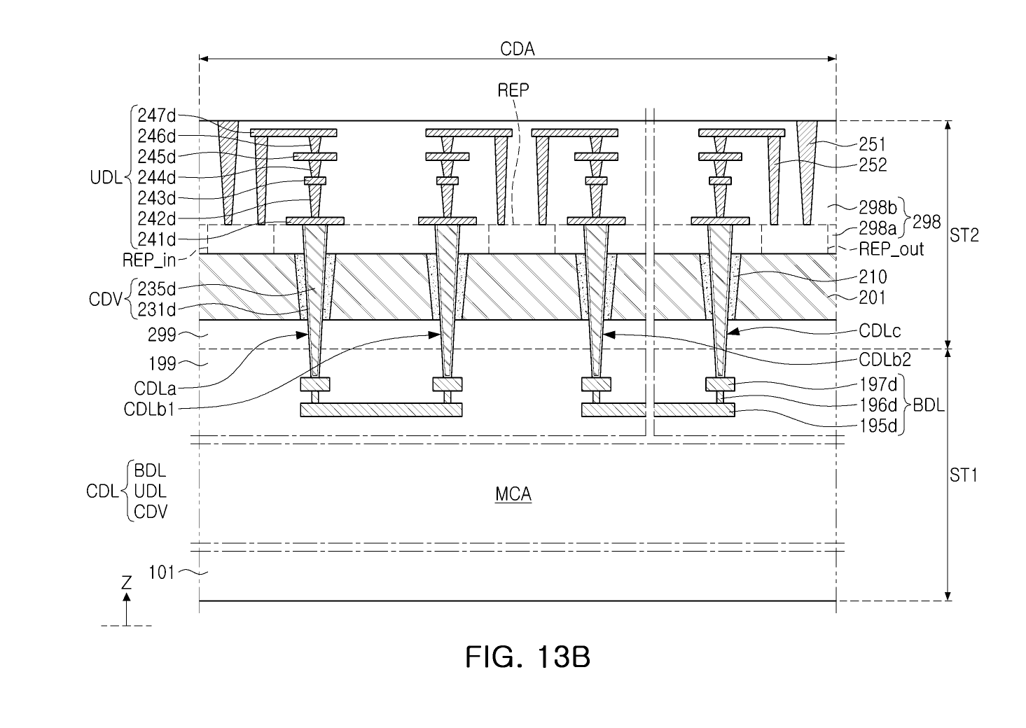

Referring to FIGS. 13A and 13B, peripheral routing interconnection structures PRS may be formed on the peripheral contact plugs 230 in a central area CA to connect peripheral contact plugs 230 and peripheral transistors pTR. The upper detection interconnection structures UDL may be formed on the detection plugs CDV in a crack detection area CDA to form crack detection lines CDL. The peripheral routing interconnection structures PRS and the upper detection interconnection structures UDL may be formed in the same process, each of which may include a plurality of interconnection lines and vias connecting the plurality of interconnection lines.

A method for manufacturing a semiconductor device may further include forming a second peripheral insulating layer 298b covering the peripheral routing interconnection structures PRS and the upper detection interconnection structures UDL, and forming first and second connection plugs 251 and 252 connected to the input driver REP_in, the output driver REP_out and at least one repeater REP in the crack detection area CDA. By forming the second peripheral insulating layer 298b covering the peripheral routing interconnection structures PRS and the upper detection interconnection structures UDL, the peripheral insulation structure 298 may be formed. The first connection plugs 251 may be connected to the input driver REP_in and the output driver REP_out by penetrating through the second peripheral insulating layer 298b. The second connection plugs 252 may be formed prior to the formation of the upper detection interconnection structures UDL, and the upper detection interconnection structures UDL may be connected to the input driver REP_in, the output driver REP_out, and at least one repeater REP through the second connection plugs 252.

Referring to FIG. 7, a crack detection structure CDS may be formed by forming input/output pads P1 and P2 on the peripheral insulation structure 298 of the second structure ST2 to be connected to the first connection plugs 251.

According to an aspect of the present disclosure, a method of manufacturing a semiconductor device according to example embodiments of the present disclosure may include: forming a first structure including memory cells, cell routing interconnection structures connected to the memory cells and formed in a central area, and a cell insulation structure covering the memory cells and the cell routing interconnection structures; forming lower detection interconnection structures in a crack detection area surrounding the central area within the cell insulation structure; forming a second structure including a semiconductor body, a rear insulating layer formed below the semiconductor body, peripheral transistors formed on a peripheral circuit area of the semiconductor body, and a first peripheral insulating layer covering the semiconductor body and the peripheral transistors; bonding the cell insulation structure of the first structure to the rear insulating layer of the second structure; forming peripheral contact plugs overlapping the central area and connected to the cell routing interconnection structure and detection plugs overlapping the crack detection area and connected to the lower detection interconnection structures; forming peripheral routing interconnection structures connected to the peripheral contact plug; and forming upper detection interconnection structures connected to the detection plugs.

According to an example embodiment, each of the peripheral contact plugs and the detection plugs may penetrate through the first peripheral insulating layer, the semiconductor body, the rear insulating layer and the cell insulation structure.

According to an example embodiment, the lower detection interconnection structures are not connected to the memory cells.

According to an example embodiment, the lower detection interconnection structures and the upper detection interconnection structures may be connected to each other.

According to an example embodiment, a method of manufacturing a semiconductor device may further include: forming a second peripheral insulating layer covering the peripheral routing interconnection structures and the upper detection interconnection structures on the first peripheral insulating layer; and forming an input pad connected to a first upper detection interconnection structure, among the upper detection interconnection structures; and forming an output pad connected to a second upper detection interconnection structure, among the upper detection interconnection structures.

According to an example embodiment, the forming the first structure may further include: forming memory cells on a semiconductor substrate; forming cell routing interconnection structures connected to the memory cells; forming the lower detection interconnection structures along an edge of the semiconductor substrate; and forming the cell insulation structure covering the memory cells, the cell routing interconnection structures and the lower detection interconnection structures.

According to an example embodiment, the forming the lower detection interconnection structures may include forming a first lower detection interconnection structure, a second lower detection interconnection structure on the first lower detection interconnection structure, and a lower detection via connecting the first lower detection interconnection structure and the second lower detection interconnection structure.

According to an example embodiment, the detection plugs may be formed along an edge of the semiconductor body.

According to an example embodiment, the forming the second structure may further include forming at least one repeater within the semiconductor body along the edge of the semiconductor body, and the upper detection interconnection structures may connect the at least one repeater and the detection plugs.

According to an example embodiment, the lower detection interconnection structures, the upper detection interconnection structures, and detection plugs connecting the lower detection interconnection structures and the upper detection interconnection structures may be included in a crack detection structure having a circular loop shape surrounding the peripheral circuit area.

A semiconductor device according to example embodiments of the present disclosure may include a first structure, a second structure bonded to the first structure, and a crack detection structure disposed over the first structure and the second structure and surrounding a peripheral circuit area of the second structure and including a plurality of crack detection lines connected to each other. Accordingly, since cracks in the first structure and the second structure may be detected through one crack detection structure, a semiconductor device having increased reliability may be provided.

While example embodiments have been illustrated and described above, it is to be apparent to those skilled in the art that modifications and variations may be made within a scope not departing from the spirit and region of the present disclosure as defined by the appended claims.

What is claimed is:

1. A semiconductor device, comprising:
a first structure comprising memory cells, cell routing interconnection structures coupled with the memory cells, and a cell insulation structure at least partially covering the memory cells and the cell routing interconnection structures;
a second structure on the first structure in a vertical direction, at least partially overlapping the first structure, and comprising a peripheral circuit area; and
a crack detection structure comprising a plurality of crack detection lines disposed over the first structure and the second structure and at least partially surrounding the peripheral circuit area,
wherein crack detection lines of the plurality of crack detection lines are coupled with each other,
wherein the second structure comprises:
a semiconductor body comprising peripheral active areas;
a rear insulating layer below the semiconductor body and bonded to the cell insulation structure;
peripheral transistors disposed in the peripheral circuit area and within the peripheral active areas; and
a peripheral insulation structure on the semiconductor body and at least partially covering the peripheral transistors,
wherein each crack detection line of the plurality of crack detection lines comprises:
a lower detection interconnection structure within the cell insulation structure;
an upper detection interconnection structure within the peripheral insulation structure; and
a detection plug at least partially penetrating through a portion of the peripheral insulation structure, the semiconductor body, the rear insulating layer, and a portion of the cell insulation structure, and coupling the lower detection interconnection structure with the upper detection interconnection structure.

2. The semiconductor device of claim 1, wherein the crack detection structure comprises a circular loop shape at least partially surrounding the peripheral circuit area.

3. The semiconductor device of claim 1, wherein the crack detection structure further comprises:
an input pad coupled with a first crack detection line of the plurality of crack detection lines; and
an output pad coupled with a second crack detection line of the plurality of crack detection lines,
wherein the input pad and the output pad are on the peripheral insulation structure of the second structure,
wherein the first crack detection line is disposed at a first end of the crack detection structure, and
wherein the second crack detection line is disposed at a second end of the crack detection structure.

4. The semiconductor device of claim 3, wherein the crack detection structure further comprises:
at least one repeater coupled with the plurality of crack detection lines and disposed in the semiconductor body,
wherein the at least one repeater is configured to:
amplify a signal input through the input pad, and
output the amplified signal.

5. The semiconductor device of claim 1, further comprising:
a through-insulating pattern at least partially penetrating through the semiconductor body,
wherein the detection plug at least partially penetrates through the through-insulating pattern.

6. The semiconductor device of claim 1, wherein the detection plug comprises:
a conductive pillar; and
a conductive barrier layer at least partially covering a side surface and a bottom surface of the conductive pillar.

7. The semiconductor device of claim 1, wherein the lower detection interconnection structure is detached from the cell routing interconnection structures.

8. The semiconductor device of claim 1, wherein the second structure further comprises:
peripheral routing interconnection structures coupled with the peripheral transistors; and
peripheral contact plugs coupling the peripheral routing interconnection structures with the cell routing interconnection structures.

9. The semiconductor device of claim 8, wherein each of the peripheral contact plugs at least partially penetrates through the portion of the peripheral insulation structure, the semiconductor body, the rear insulating layer, and the portion of the cell insulation structure.

10. The semiconductor device of claim 1, wherein each of the memory cells comprises:
channel structures extending on a substrate in a first direction and spaced apart from each other in a second direction, the second direction intersecting the first direction;
bit lines in contact with a first end of each of the channel structures;
gate electrodes extending in the second direction and at least partially surrounding the channel structures; and
an information storage structure in contact with a second end of each of the channel structures opposite the first end of the channel structures.

11. The semiconductor device of claim 1, wherein the lower detection interconnection structure comprises:
a first lower detection interconnection line;
a second lower detection interconnection line on the first lower detection interconnection line; and
a lower detection via coupling the first lower detection interconnection line with the second lower detection interconnection line.

12. The semiconductor device of claim 11, wherein the upper detection interconnection structure comprises:
a plurality of upper detection interconnection lines on the detection plug; and
a plurality of upper detection vias coupling the plurality of upper detection interconnection lines,
wherein the plurality of upper detection interconnection lines comprise:
a first upper detection interconnection line;
a second upper detection interconnection line on the first upper detection interconnection line;
a third upper detection interconnection line on the second upper detection interconnection line; and
a fourth upper detection interconnection line on the third upper detection interconnection line, and
wherein the plurality of upper detection vias comprise:
a first upper detection via between the first upper detection interconnection line and the second upper detection interconnection line;
a second upper detection via between the second upper detection interconnection line and the third upper detection interconnection line; and
a third upper detection via between the third upper detection interconnection line and the fourth upper detection interconnection line.

13. The semiconductor device of claim 12, wherein the crack detection structure is in a floating state and detached from the cell routing interconnection structures and a peripheral routing interconnection structure of the second structure.

14. A semiconductor device, comprising:
a first structure comprising a memory area;
a second structure comprising a peripheral circuit area on the first structure in a vertical direction and at least partially overlapping the memory area; and
a crack detection structure comprising:
a plurality of crack detection lines disposed over the first structure and the second structure and at least partially surrounding the peripheral circuit area;
an input pad on the second structure coupled with the plurality of crack detection lines; and
an output pad on the second structure coupled with the plurality of crack detection lines;
wherein crack detection lines of the plurality of crack detection lines are coupled with each other,
wherein the second structure comprises:
a semiconductor body comprising peripheral active areas;
a rear insulating layer below the semiconductor body;
a peripheral transistor in the peripheral circuit area and within the peripheral active areas, and comprising:
a first peripheral source/drain;
a second peripheral source/drain;
a peripheral channel region between the first peripheral source/drain and the second peripheral source/drain; and
a peripheral gate on the peripheral channel region;
a peripheral insulation structure on the semiconductor body;
a peripheral routing interconnection structure within the peripheral insulation structure and coupled with the peripheral transistor; and
a peripheral contact plug in the peripheral circuit area, coupled with the peripheral routing interconnection structure, and at least partially penetrating through the semiconductor body and the rear insulating layer,
wherein each crack detection line of the plurality of crack detection lines comprises:
a lower detection interconnection structure within the first structure;
an upper detection interconnection structure within the peripheral insulation structure; and
a detection plug at least partially penetrating through the peripheral insulation structure below the upper detection interconnection structure, the semiconductor body and the rear insulating layer, and coupling the lower detection interconnection structure with the upper detection interconnection structure.

15. The semiconductor device of claim 14, wherein the plurality of crack detection lines comprise:
a first crack detection line coupled with the input pad;
a second crack detection line adjacent to the first crack detection line; and
a third crack detection line adjacent to the second crack detection line, and
wherein the crack detection structure further comprises:
an input driver between the input pad and the first crack detection line; and
an output driver between the output pad and the third crack detection line.

16. The semiconductor device of claim 15, wherein the crack detection structure further comprises:
at least one repeater within the semiconductor body between the first crack detection line and the third crack detection line; and
at least one connection plug coupled with the at least one repeater and within the peripheral insulation structure, and
wherein the at least one connection plug is coupled with the upper detection interconnection structure of the second crack detection line.

17. The semiconductor device of claim 14, wherein the first structure comprises:
memory cells within the memory area;
a cell insulation structure on the memory cells; and
a cell routing interconnection structure within the cell insulation structure and electrically coupled with the memory cells, and
wherein the lower detection interconnection structure is within the cell insulation structure.

18. The semiconductor device of claim 17, wherein the detection plug is coupled with the lower detection interconnection structure by at least partially penetrating through the cell insulation structure on the lower detection interconnection structure, and
wherein a lower surface of the detection plug is at a same level as a lower surface of the peripheral contact plug.

19. The semiconductor device of claim 14, wherein the peripheral routing interconnection structure does not overlap the plurality of crack detection lines in the vertical direction.

20. A semiconductor device, comprising:
a first structure comprising a semiconductor substrate, and a first insulation structure at least partially covering the semiconductor substrate;
a second structure on the first structure; and
a crack detection structure comprising:
a plurality of crack detection lines disposed over the first structure and the second structure; and
at least one repeater between the plurality of crack detection lines,
wherein crack detection lines of the plurality of crack detection lines are coupled with each other,
wherein the second structure comprises:
a semiconductor body comprising active areas;
a rear insulating layer below the semiconductor body and in contact with the first insulation structure;
transistors disposed within the active areas; and
a second insulation structure at least partially covering the semiconductor body and the transistors,
wherein the crack detection structure at least partially surrounds the transistors, and
wherein the plurality of crack detection lines comprise:
a lower detection interconnection structure within the first insulation structure;
an upper detection interconnection structure within the second insulation structure; and
a detection plug at least partially penetrating through a portion of the second insulation structure below the upper detection interconnection structure, the semiconductor body, the rear insulating layer, and a portion of the first insulation structure on the lower detection interconnection structure, and coupling the lower detection interconnection structure with the upper detection interconnection structure.
